(19) United States
(12) Patent Application Publication
(10) Pub. No.: US 2026/0317887 A1
(43) Pub. Date: Oct. 15, 2026

(54) BORON-BASED AND HIGH-ENTROPY MAGNETIC MATERIALS

(71) Applicant: Georgetown University, Washington, DC (US)

(72) Inventors: Kai Liu, Falls Church, VA (US); Willie Beeson, Alexandria, VA (US)

(21) Appl. No.: 19/290,945

(22) Filed: Aug. 5, 2025

Related U.S. Application Data
(63) Continuation-in-part of application No. 18/842,341, filed on Mar. 13, 2023.
(60) Provisional application No. 63/319,150, filed on Mar. 11, 2022.
(60) Provisional application No. 63/679,276, filed on Aug. 5, 2024.

(51) Int. Cl. C23C 14/06; C23C 14/34; C23C 14/58; H01F 1/047

(52) U.S. Cl. CPC C23C 14/067; C23C 14/3464; C23C 14/5806; H01F 1/047

(57) ABSTRACT

A composition of borides comprising boron and a plurality of transition metals including iron (Fe), cobalt (Co), nickel (Ni), and manganese (Mn), wherein: an atomic ratio of boron to total transition metals ranges from 20:80 to 45:55; Fe is present in an amount from 25% to 40% of the total transition metal content; Co is present in an amount from 5% to 20% of the total transition metal content; Ni is present in an amount from 5% to 20% of the total transition metal content; and Mn is present in an amount from 20% to 35% of the total transition metal content.

### CROSS-REFERENCE TO RELATED PATENT APPLICATION

The present patent application claims priority to U.S. Provisional Patent Application No. 63/319,150, filed Mar. 11, 2022, and entitled “Boron-Based Magnetic Materials”, U.S. patent application Ser. No. 18/842,341, filed Mar. 13, 2023, and entitled “Boron-Based and High-Entropy Magnetic Materials,” the disclosures of which is incorporated herein by reference in their entirety.

This invention was made with government support under grant ECCS-2151809 awarded by the National Science Foundation. The government has certain rights in the invention.

### BACKGROUND OF THE INVENTION

The present invention relates to novel magnetic materials fabricated using high entropy alloys and also incorporating boron with high entropy alloys.

Boron has historically played an important role in the development of high-performance permanent magnets relying on high magnetocrystalline anisotropy. After measurements of Y—Co alloys in the 1960s revealed an exceptionally high magnetic anisotropy, there grew a dominant focus on rare-earth-transition metal alloys for use in permanent magnets, quickly leading to the formulation of the widely used Sm—Co magnet. Unfortunately, the Sm—Co materials are brittle and prone to cracking and chipping. While there was a strong motivation to replace Co with the more abundant Fe, studies on the binary rare-earth-Fe systems revealed very few stable alloys, none of which possessed suitable magnetic properties. In 1984, it was discovered that small additions of boron (6 at. %) stabilized a tetragonal intermetallic in the ternary Nd—Fe—B system with a high magnetocrystalline anisotropy and a high saturation magnetization. While the magnetic properties arise from the combination of high spin-orbit coupling due to the Nd 5f electrons and high spin-polarization due to the Fe 3d electrons, the role of B is critical, as Nd and Fe do not otherwise form stable binary compounds.

Application of high entropy materials in permanent magnets has the potential to address numerous challenges in permanent magnet design. Foremost is the elimination of rare-earth metals in magnetic materials by the discovery of novel rare-earth free material phases with high magnetic anisotropy. Additionally, there is the potential to achieve good mechanical and corrosion resistance properties. For example, Sm—Co magnets lack ductility, making them difficult to process. High entropy materials are known to have excellent mechanical properties, such as hardness and ductility, which are tunable by composition. Furthermore, Nd—Fe—B magnets are susceptible to corrosion, whereas high entropy materials generally show good corrosion resistance.

The rare earth elements are scarce in the earth's crust and thus costly. In addition to the physical scarcity, politically-induced scarcity may also artificially increase the price of these elements.

High magnetic anisotropy materials are critically important to permanent magnet technologies, which have applications in numerous industry sectors, including hybrid/electric vehicles, magnetically levitated trains, wind turbines, power storage, consumer electronics, magnetic refrigeration, etc.

The best such materials typically contain expensive rare-earth and noble metals such as NdFeB, SmCo, L1₀ FePt, the latter of whose crystalline structures is illustrated in FIG. 1. There is much effort to eliminate or reduce use of rare-earth and noble metals. Some compounds such as L1₀ FeNi, MnAl satisfy these constraints but most potential binary alloy compositions have been exhausted and there are no commercially viable replacements yet.

Alloys of FePt in a face-centered tetragonal L1₀ phase have important applications in magnetic recording media, but contain the precious/noble metal platinum. Intense efforts have focused on other L1₀ phases such as FeNi and MnAl, each possessing challenges to realization, primarily due to kinetic and thermodynamic barriers.

Accordingly, a need arises for materials which exhibit high magnetocrystalline anisotropy as well as other attractive attributes such as ductility, hardness, stability at high temperatures, and resistance to corrosion but which employ earth-abundant elements and a need also arises for methods to produce such materials.

### SUMMARY OF THE INVENTION

This disclosure relates to methods of fabricating high anisotropy magnetic materials.

In an embodiment, high anisotropy magnetic material may be fabricated by sputtering a thin film onto a substrate using at least three sputtering targets. A first sputtering target may comprise an elemental ferromagnetic material. A second sputtering target may comprise a transition metal other than the elemental ferromagnetic material. A third sputtering target may comprise boron. After sputtering a thin film onto the substrate using the three sputtering targets, the sputtered thin film on the substrate may be annealed. The annealing may comprise a rapid thermal annealing. In an embodiment, the rapid thermal annealing may comprise a heating step wherein the substrate is heated at a ramp rate greater than or equal to 10° C./s for at least 10 seconds and wherein the rapid thermal annealing further comprises a cooling step of at least 10 seconds. The elemental magnetic material may comprise one of Fe, Co, or Ni. In an embodiment, the sputtering step may comprise co-sputtering of all three targets at the same time. In an embodiment, the sputtering step may comprise alternately sputtering a layer of boron and sputtering a layer of the two other materials by co-sputtering the first target and the second target.

In another embodiment, the sputtering step may comprise sputtering of the targets individually and sequentially in any combination. In another embodiment, the sputtering step may comprise sputtering any number of the targets simultaneously or sequentially in any combination.

In an embodiment, a high entropy alloy, high anisotropy magnetic material may be fabricated by sputtering a thin film onto a substrate using at least five sputtering targets. A first sputtering target may comprise an elemental ferromagnetic material. A second sputtering target may comprise a first non-rare-earth metal other than the elemental ferromagnetic material. A third sputtering target may comprise a second non-rare-earth metal other than the elemental ferromagnetic material. A fourth sputtering target may comprise a third non-rare-earth metal other than the elemental ferromagnetic material. A fifth sputtering target may comprise a fourth non-rare-earth metal other than the elemental ferromagnetic material. After sputtering a thin film onto the substrate using the five sputtering targets, the sputtered thin film on the substrate may be annealed. The annealing may comprise a rapid thermal annealing. In an embodiment, the rapid thermal annealing may comprise a heating step wherein the substrate is heated at a ramp rate greater than or equal to 10° C./s for at least 10 seconds and wherein the rapid thermal annealing further comprises a cooling step of at least 10 seconds. The elemental magnetic material may comprise one of Fe, Co, or Ni. In an embodiment, the first non-rare-earth metal comprises Mn, the second non-rare-earth metal comprises Cu, the third non-rare-earth metal comprises the one of Fe, Co, or Ni which was not selected for the first target, and the fourth non-rare-earth metal comprises the remaining unselected element of Fe, Co, or Ni. In an embodiment, the sputtering step may comprise co-sputtering of all five targets at the same time.

In another embodiment, the sputtering step may comprise sputtering of the five targets individually and sequentially in any combination. In another embodiment, the sputtering step may comprise sputtering any number of the five targets simultaneously or sequentially in any combination.

In an embodiment, a high entropy alloy, high anisotropy magnetic material may be fabricated by sputtering a thin film onto a substrate using at least six sputtering targets. A first sputtering target may comprise an elemental ferromagnetic material. A second sputtering target may comprise a first non-rare-earth metal other than the elemental ferromagnetic material of the first target. A third sputtering target may comprise a second non-rare-earth metal other than the elemental ferromagnetic material of the first target. A fourth sputtering target may comprise a third non-rare-earth metal other than the elemental ferromagnetic material of the first target. A fifth sputtering target may comprise a fourth non-rare-earth metal other than the elemental ferromagnetic material of the first target. The sixth sputtering target may comprise a noble metal or a post-transition metal. After sputtering a thin film onto the substrate using the six sputtering targets, the sputtered thin film on the substrate may be annealed. The annealing may comprise a rapid thermal annealing. In an embodiment, the rapid thermal annealing may comprise a heating step wherein the substrate is heated at a ramp rate greater than or equal to 10° C./s for at least 10 seconds and wherein the rapid thermal annealing further comprises a cooling step of at least 10 seconds. In an embodiment, the elemental ferromagnetic material may comprise one of Fe, Co, or Ni. In an embodiment, the noble metal or the post-transition metal may comprise at least one of Pt, Pd, or Al. In an embodiment, the sputtering step may comprise co-sputtering of all six targets at the same time. In an embodiment, the sputtering step may comprise alternatively sputtering a layer of the first five targets co-sputtered together with sputtering a layer of the sixth target. In an embodiment, the ratio of a high entropy alloy comprising the materials of the first five targets to platinum or aluminum ranges from 40:60 to 65:35.

In another embodiment, the sputtering step may comprise sputtering of the targets individually and sequentially in any combination. In another embodiment, the sputtering step may comprise sputtering any number of the targets simultaneously or sequentially in any combination.

In an embodiment, a high entropy alloy, high anisotropy magnetic material may be fabricated by sputtering a thin film onto a substrate using at least two sputtering targets. A first composite sputtering target may be created using approximately equal molar amounts of five materials. The five materials comprise: a selected elemental ferromagnetic material and four non-rare-earth metals other than the selected elemental ferromagnetic material. A second sputtering target may comprise a noble metal or post-transition metal. The thin film may be sputtered on the substrate using these two sputtering targets. After sputtering a thin film onto the substrate using the two sputtering targets, the sputtered thin film on the substrate may be annealed. The annealing may comprise a rapid thermal annealing. In an embodiment, the rapid thermal annealing may comprise a heating step wherein the substrate is heated at a ramp rate greater than or equal to 10° C./s for at least 10 seconds and wherein the rapid thermal annealing further comprises a cooling step of at least 10 seconds. In an embodiment, the elemental magnetic material may comprise one of Fe, Co, or Ni. In an embodiment, the noble metal or the post-transition metal comprises at least one of Pt, Pd, or Al. In an embodiment, the sputtering step may comprise co-sputtering of the first target and the second target at the same time. In an embodiment, the sputtering step may comprise alternatively sputtering a layer of the first target with sputtering a layer of the second target. In an embodiment, the ratio of a high entropy alloy comprising the material of the first target to the material of the second target is in the range 40:60 to 65:35.

In another embodiment, the sputtering step may comprise sputtering of the targets individually and sequentially in any combination. In another embodiment, the sputtering step may comprise sputtering any number of the targets simultaneously or sequentially in any combination.

In an embodiment, a high entropy alloy, high anisotropy magnetic material may be fabricated by sputtering a thin film onto a substrate using at least six sputtering targets. A first sputtering target may comprise an elemental ferromagnetic material. A second sputtering target may comprise a first non-rare-earth metal other than the elemental ferromagnetic material of the first target. A third sputtering target may comprise a second non-rare-earth metal other than the elemental ferromagnetic material of the first target. A fourth sputtering target may comprise a third non-rare-earth metal other than the elemental ferromagnetic material of the first target. A fifth sputtering target may comprise a fourth non-rare-earth metal other than the elemental ferromagnetic material of the first target. The sixth sputtering target may comprise boron. After sputtering a thin film onto the substrate using the six sputtering targets, the sputtered thin film on the substrate may be annealed. The annealing may comprise a rapid thermal annealing. In an embodiment, the rapid thermal annealing may comprise a heating step wherein the substrate is heated at a ramp rate greater than or equal to 10° C./s for at least 10 seconds and wherein the rapid thermal annealing further comprises a cooling step of at least 10 seconds. The elemental magnetic material may comprise one of Fe, Co, or Ni. In an embodiment, the sputtering step may comprise co-sputtering of all six targets at the same time. In an embodiment, the sputtering step may comprise alternatively sputtering a layer of the first five targets co-sputtered together with sputtering a layer of boron. In an embodiment, the ratio of a high entropy alloy comprising the materials of the first five targets to boron ranges from 55:45 to 80:20.

In another embodiment, the sputtering step may comprise sputtering of the targets individually and sequentially in any combination. In another embodiment, the sputtering step may comprise sputtering any number of the targets simultaneously or sequentially in any combination.

In an embodiment, a high entropy alloy, high anisotropy magnetic material may be fabricated by sputtering a thin film onto a substrate using at least two sputtering targets. A first sputtering target may be created using approximately equal molar amounts of five materials. The five materials comprise: a selected elemental ferromagnetic material and four non-rare-earth metals other than the selected elemental ferromagnetic material. A second sputtering target may comprise boron. The thin film may be sputtered on the substrate using these two sputtering targets. After sputtering a thin film onto the substrate using the two sputtering targets, the sputtered thin film on the substrate may be annealed. The annealing may comprise a rapid thermal annealing. In an embodiment, the rapid thermal annealing may comprise a heating step wherein the substrate is heated at a ramp rate greater than or equal to 10° C./s for at least 10 seconds and wherein the rapid thermal annealing further comprises a cooling step of at least 10 seconds. The elemental magnetic material may comprise one of Fe, Co, or Ni. In an embodiment, the sputtering step may comprise co-sputtering of both targets at the same time. In an embodiment, the sputtering step may comprise alternatively sputtering a layer of the first target with sputtering a layer of boron. In an embodiment, the ratio of a high entropy alloy comprising the materials of the first target to the second target is in the range from 55:45 to 80:20.

In another embodiment, the sputtering step may comprise sputtering of the targets individually and sequentially in any combination. In another embodiment, the sputtering step may comprise sputtering any number of the targets simultaneously or sequentially in any combination.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and the invention may admit to other equally effective embodiments.

FIG. 1 illustrates the L1₀ crystal structure.

FIG. 2 illustrates an exemplary crystal structure of a boron-related material in the C16 phase.

FIG. 3 illustrates an exemplary crystal structure of a high entropy alloy.

FIG. 4 illustrates the atomic radius dispersity as a function of the overall electronegativity difference, adapted from: K. Yao et al, Scripta Mater. 194, 113674 (2021).

FIG. 5 illustrates an X-ray diffraction (XRD) scan of an as-deposited high entropy material (FeCoNiMnCu)Pt.

FIG. 6 illustrates grazing incidence X-ray diffraction (top) and 0-20 (bottom) for a high entropy material (FeCoNiMnCu)Pt after rapid thermal annealing.

FIG. 7 illustrates a hysteresis loop of an as-deposited high entropy material (FeCoNiMnCu)Pt.

FIG. 8 illustrates a hysteresis loop of a high entropy material (FeCoNiMnCu)Pt after rapid thermal annealing.

FIG. 9 illustrates an X-ray diffraction scan of FeCoNiMnCu films with various deposition temperatures and also after a rapid thermal annealing.

FIG. 10 illustrates scanning electron microscopy images of an exemplary high entropy FeCoNiMnCu film under increasing rapid thermal annealing duration.

FIG. 11 illustrates hysteresis loops (top) and first order reversal curve (FORC) analysis (bottom) of FeCoNiMnCu films in different conditions.

FIG. 12 illustrates the dependence of coercivity on angle for a high entropy FeCoNiMnCu film.

FIG. 13 illustrates the in-plane (left) and out-of-plane (right) hysteresis loops (top) and FORC distributions (bottom) for a high entropy FeCoNiMnCu)Pt film.

FIG. 14 illustrates an XRD scan of a high entropy, boron-containing material.

FIG. 15 illustrates a hysteresis loop of a high entropy, boron-containing material.

FIG. 16 illustrates a hysteresis loop of a high entropy, boron-containing material.

FIG. 17 illustrates GIXRD scans for a boron-containing material.

FIG. 18 illustrates an XRD scan for a boron-containing material.

FIG. 19 illustrates a hysteresis loop for a boron-containing material.

FIG. 20 illustrates hysteresis loops for boron-containing materials.

FIG. 21 illustrates a set of exemplary process steps for fabricating a magnetic material.

FIG. 22 illustrates a set of exemplary process steps for fabricating a magnetic material.

FIGS. 23a and 23b illustrate an XRD scan (left) and hysteresis loop (right) of a (FeCoNiMn)₂B film.

FIG. 24 illustrates a schematic of the combinatorial sputtering setup.

FIGS. 25a-25f illustrate the hysteresis loops and corresponding heatmaps of the coercivity and magnetization for two sets of combinatorial boride films.

FIG. 26 illustrates quaternary diagrams of the coercivity (top) and magnetization (bottom) for the combinatorial boride films.

FIG. 27 illustrates the hysteresis loops of select combinatorial boride samples measured at 5 K.

FIG. 28 illustrates a map of the magnetic anisotropy in the C16 boride system.

FIG. 29 illustrates a histogram of the effective number of valence electrons for the combinatorial boride films.

Other features of the present embodiments will be apparent from the Detailed Description that follows.

### DETAILED DESCRIPTION

In the following detailed description of the preferred embodiments, reference is made to the accompanying drawings, which form a part hereof, and within which are shown by way of illustration specific embodiments by which the invention may be practiced. It is to be understood that other embodiments may be utilized and structural changes may be made without departing from the scope of the invention. Electrical, mechanical, logical, and structural changes may be made to the embodiments without departing from the spirit and scope of the present teachings. The following detailed description is therefore not to be taken in a limiting sense, and the scope of the present disclosure is defined by the appended claims and their equivalents.

The following disclosure discusses the present invention with reference to the examples shown in the accompanying drawings, though does not limit the invention to those examples.

The use of any and all examples, or exemplary language (e.g., “such as”) provided herein is intended merely to better illuminate the invention and does not pose a limitation on the scope of the invention unless otherwise claimed. No language in the specification should be construed as indicating any non-claimed element as essential or otherwise critical to the practice of the invention, unless made clear in context.

As used herein, the singular forms “a,” “an,” and “the” include plural referents unless the context clearly dictates otherwise. Unless indicated otherwise by context, the term “or” is to be understood as an inclusive “or.” Terms such as “first”, “second”, “third”, etc. when used to describe multiple devices or elements, are so used only to convey the relative actions, positioning and/or functions of the separate devices, and do not necessitate either a specific order for such devices or elements, or any specific quantity or ranking of such devices or elements.

The word “substantially”, as used herein with respect to any property or circumstance, refers to a degree of deviation that is sufficiently small so as to not appreciably detract from the identified property or circumstance. The exact degree of deviation allowable in a given circumstance will depend on the specific context, as would be understood by one having ordinary skill in the art.

Use of the terms “about” or “approximately” are intended to describe values above and/or below a stated value or range, as would be understood by one having ordinary skill in the art in the respective context. In some instances, this may encompass values in a range of approx. +/−10%; in other instances there may be encompassed values in a range of approx. +/−5%; in yet other instances values in a range of approx. +/−2% may be encompassed; and in yet further instances, this may encompass values in a range of approx. +/−1%.

It will be understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof, unless indicated herein or otherwise clearly contradicted by context.

Recitations of a value range herein, unless indicated otherwise, serves as a shorthand for referring individually to each separate value falling within the stated range, including the endpoints of the range, each separate value within the range, and all intermediate ranges subsumed by the overall range, with each incorporated into the specification as if individually recited herein.

Unless indicated otherwise, or clearly contradicted by context, methods described herein can be performed with the individual steps executed in any suitable order, including: the precise order disclosed, without any intermediate steps or with one or more further steps interposed between the disclosed steps; with the disclosed steps performed in an order other than the exact order disclosed; with one or more steps performed simultaneously; and with one or more disclosed steps omitted.

The present disclosure relates to the fabrication of magnetic materials. In an embodiment, the materials may comprise boron. In an embodiment, the magnetic materials may comprise a high entropy alloy. Specifically, in some embodiments, boron may be used to induce an intermetallic phase (called L1₀ in the Stukturbericht notation) in certain metal or metal-boron compounds after annealing, and this intermetallic phase may have desirable magnetic properties. In addition, adding boron to high entropy materials may also aid in the creation of materials with good materials properties (e.g. ductility, strength, corrosion resistance) in addition to also having desirable magnetic properties.

This disclosure describes how to fabricate high entropy alloys and also how to utilize boron to stabilize rare-earth-free high magnetic anisotropy materials for use in permanent magnet technologies and magnetic recording. The disclosure comprises two central aspects on different materials systems: one comprising metallic high entropy alloys and the other using boron to achieve stable, rare-earth-free, C16 phase materials. These materials all display enhanced magnetic anisotropy. The boron-compounds may chemically stabilize the uniaxial symmetry of these alloys.

This disclosure describes examples of how to fabricate high entropy compounds with high magnetic anisotropy. For example, films of FeCoNiMnCu may be deposited by sputtering followed by annealing. For example, films may be deposited using DC sputtering or rf sputtering.

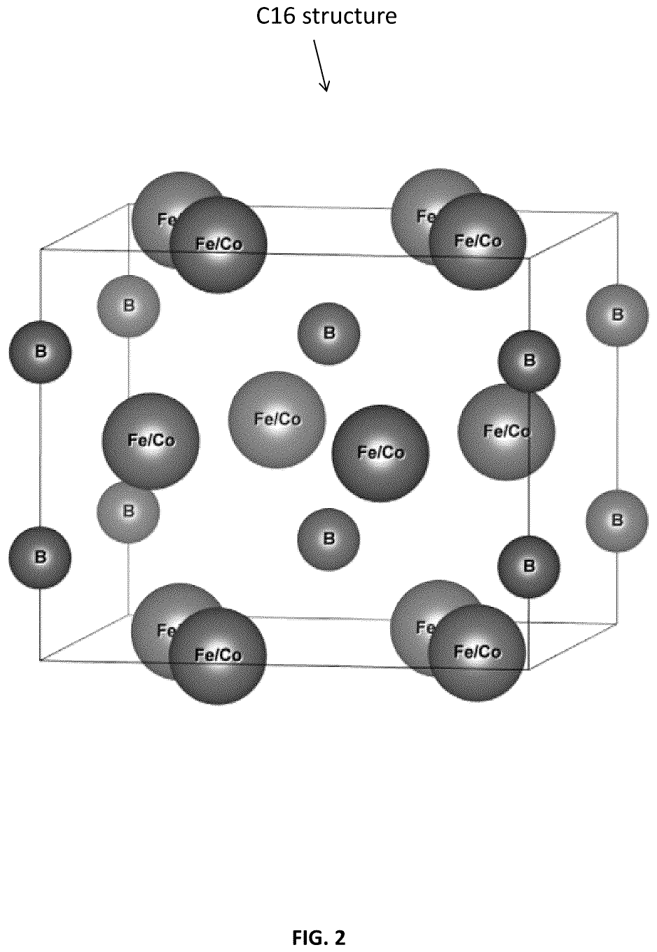

Examples of these materials include the stabilization and anisotropy enhancement of the L1₀ (intermetallic) phases of materials such as FeNi and MnAl. Examples of boron-containing materials include, for example, C16 high entropy borides, as shown in FIG. 2.

High entropy alloys (HEAs) offer a huge unexplored composition space which may contain new rare-earth/noble metal-free phase with high anisotropy, in combination with other desirable properties. High entropy alloys often exhibit high symmetry structures, and chemical disorder increases with entropy whereas uniaxial structure/chemical order are important foundations of the magnetic properties in high anisotropy materials. Careful choice of composition and a suitable fabrication route enable the stabilization of high entropy material phases which exhibit uniaxial structure and chemical order. In an example, boron may be used to achieve this enhanced stability. Rapid thermal annealing of thin films has been shown to be an effective method of producing ordering in uniaxially symmetric binary phases, including ones which are metastable or difficult to form by other means (e.g., FePt, FeNi, MnAl).

High entropy alloys are a class of materials traditionally defined to contain 5 or more elements in concentrations of 5-35 at. %, which may exist as stable or metastable single phases due to their high configurational entropy. The entropy-stabilization effect implies a vast number of unexplored material phases with potential to exhibit various physical properties. HEA studies have predominantly focused on their exceptional mechanical properties, namely combinations of strength, hardness, and ductility. In recent years, however, several systems have been reported which exhibit other attractive and functional properties, such as hydrogen storage capability, thermoelectric properties, superconductivity, magnetocaloric properties, and soft magnetic properties.

A prospect which remains largely unexplored is the existence of HEAs with hard magnetic properties, particularly which originate from high magnetocrystalline anisotropy. Most known HEAs fall in the category of soft or semi-hard magnetic materials, with coercivities in the range of 1 Oe<H_{c}<100 Oe. However, H_{c} as high as 1200 Oe have been reported. The coercivity is highly influenced by the microstructure which may differ between reported HEA systems especially depending on the fabrication conditions. So far, there has been a lack of HEA systems with high coercivity resulting from high magnetocrystalline anisotropy of a single multi-principal element phase. Maximum entropy phases at the compositional center, which have been the focus of HEA studies, are thought to consist of uniform chemical disorder and typically exhibit cubic crystal structures, whereas lower-symmetry crystal structure and chemical order play an important role in the magnetic properties of high anisotropy materials.

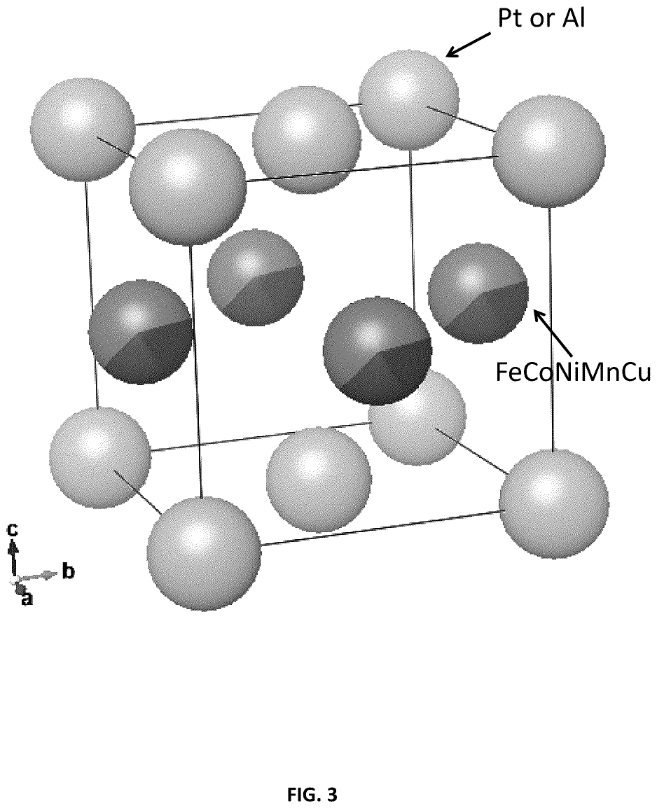

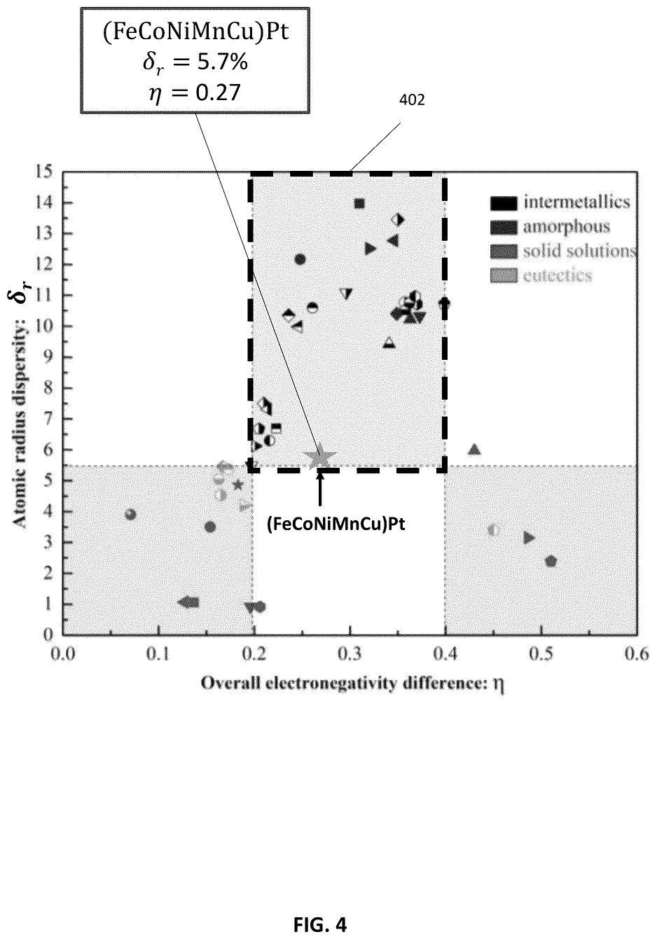

FIG. 3 and FIG. 4 illustrate why platinum may help improve the magnetic properties of these films. FIG. 3 illustrates a hypothetical tetragonal crystalline structure with Pt at the ends and intermixed with FeCoNiMnCu layers. FIG. 4 shows the atomic radius dispersity as a function of the overall electronegativity difference, adapted from K. Yao et al, Scripta Mater. 194, 113674 (2021). The (FeCoNiMnCu)Pt film properties are noted by the star. Other metals than platinum may also be employed in a similar manner, for instance aluminum. Single-phase HEAs may exhibit long-range chemical order through the emergence of multiple sublattices with different levels of configurational entropy and preferential site occupation. The term high entropy intermetallic (HEIs) has been used to describe this type of HEA. Unlike the conventional HEA design approach which generally seeks to minimize the magnitude of mixing enthalpy |ΔHₘᵢₓ| while maximizing configurational entropy ΔS_{config}, the formation of HEIs may depend on a balanced interplay of these parameters. Geometrical and electronic parameters may also be considered, as single-phase HEIs have been shown to form in the range of atomic size difference δr≥5.5% and electronegativity difference 0.2≤η≤0.4, as illustrated in FIG. 4. The atomic size difference and electronegativity difference constraints are illustrated by the dashed line box 402 in FIG. 4. One of the example materials discussed in this disclosure (FeCoNiMnCu)Pt is also highlighted by a star in the figure with the parameters given in the box. Other high entropy alloys made using mixtures of any of the transition metals, which include those elements in Groups 3 through 12 of the periodic table. For example, materials such as FeCoNiMnCr, FeCoVCuZn, and the like may be made into high entropy alloys and the addition of, for example, Pt may be used to promote the formation of the desired phase.

In the examples presented in this disclosure, a fabrication route to single-phase HEA thin films is demonstrated based on sputter deposition and thermal annealing, especially rapid thermal annealing (RTA). The magnetic properties of near-equiatomic solid-solution FeCoNiMnCu thin films, as an example, are presented and HEI design criteria are implemented to obtain an L1₀-ordered HEI by incorporation of 45 at. % Pt. Drawing from a database of binary mixing enthalpies calculated via the Miedema method, the total mixing enthalpy of the solid-solution FeCoNiMnCu is estimated from the composition weighted average as ΔHₘᵢₓ=1.23 kJ/mol. The small positive enthalpy is outweighed by the ideal configurational entropic contribution to the free energy at room-temperature −TS_{config}=−3.9 kJ/mol. The valence electron concentration (VEC) of 9 predicts a face-centered-cubic (fcc) structure for 3d transition metal HEAs, which is a precursor to the L1₀ structure. The system (FeCoNiMnCu)Pt also satisfies the geometric and electronic criteria for single-phase HEIs with a δr=5.7% and η=0.27.

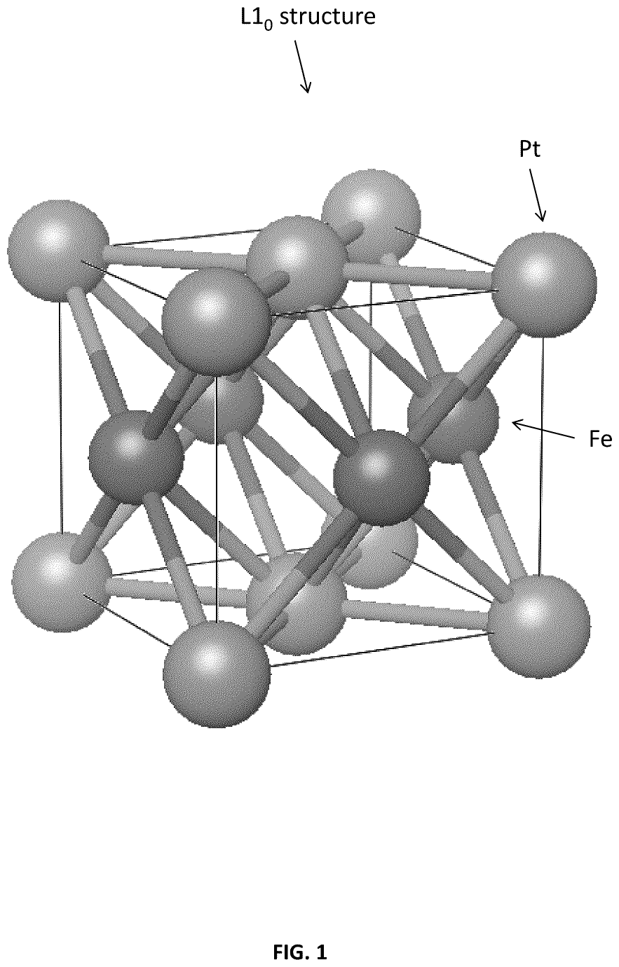

Pt-based L1₀ structure (FIG. 1) is a good testbed for fabrication of high entropy intermetallic with high anisotropy, since Fe, Co, Ni, and Mn each form a stable binary L1₀ structure with Pt, therefore they are all energetically inclined to order in such a way with Pt. In an alternative embodiment aluminum could also be employed in the same manner, with the additional benefit that aluminum is more cost effective than platinum. At the same time, a solid-solution of FeCoNiMnCu has a modest total mixing enthalpy and high entropy, allowing the elements to mix comfortably on the sublattice opposite of Pt (or Al), as illustrated in FIG. 3, rather than separate to other binary phases. This composition also exists in the range of electronegativity and atomic size difference which is proposed to exhibit the stable single-phase high entropy intermetallics.

### Intermetallic Phase in Metal-Boron Compounds

Currently, the best candidates for rare-earth and noble metal-free permanent magnets, L1₀ compounds such as FeNi and MnAl, suffer from poor thermodynamic stability and kinetic limitations resulting in difficulty of production as well as deterioration of the permanent magnet properties over time. The use of boron allows for tuning of the material's free energy to favor chemical ordering into structures with high magnetic anisotropy. The small atomic size of boron allows it to bond interstitially into the L1₀ structure, improving stability without detrimentally altering the interaction between Fe and Ni giving it its high magnetic anisotropy. Currently, approaches to achieving L1₀ FeNi involve processes such as ion irradiation or plastic deformation, pose difficulties for scaling to commercial production. Incorporating boron to improve thermodynamic stability should make production by conventional means viable. L1₀ Fe—Ni—B may have the potential to rival the prevailing Nd—Fe—B in terms of magnetocrystalline anisotropy, saturation magnetization, and Curie temperature while containing no rare-earth metals.

An exciting new prospect of boron is in the design of permanent magnets free of rare-earth elements, as current rare-earth based permanent magnets are prone to price fluctuations and subject to limits due to supply chain issues. A key bottleneck for rare-earth free magnets has been their phase stability. For example, the binary L1₀ (intermetallic) phases of FeNi and MnAl exhibit high magnetocrystalline anisotropy energy densities of 1.3×10⁷ erg/cm³ and 1.7×10⁷ erg/cm³, respectively, which are comparable to other magnetic materials like MnBi at 0.89×10⁷ erg/cm³ or YCo₅ at 5.5×10⁷ erg/cm³. In this context, a high magnetocrystalline anisotropy may include an energy density at or above approximately 5×10⁶ erg/cm³. However, FeNi suffers from extraordinarily slow diffusion kinetics near its low order-disorder transition temperature, preventing its formation through a conventional annealing process defined by slower ramp rates (e.g. 2-3° C./s or slower), longer times at the peak temperature (e.g. >10 minutes), and slower cool down rates (e.g. 2-3° C./s or slower) than a rapid annealing process. In this disclosure, rapid thermal annealing is defined as having a ramp rate of 10° C./s or faster to distinguish from the conventional annealing process which uses a ramp rate ≤3° C./s. In an example, the ramp rate of the rapid thermal anneal may be 10° C./s to 500° C./s. A major factor in its slow diffusion is the low magnitude of the enthalpy of formation of the L1₀ phase, placing it on the border of stability at room-temperature. The L1₀ (intermetallic) phase of MnAl is unambiguously metastable and decomposes easily. Recent studies indicate that boron could provide a route to stabilizing the high magnetic anisotropy L1₀ phases without the need for rare earth elements. Density-functional theory calculations predict that interstitial boron, occupying the body-center of the L1₀ phase on the Ni plane, may enhance the properties of FeNi on two fronts. It may increase the magnitude of the formation enthalpy of the L1₀ phase, and more than double the magnetocrystalline anisotropy energy relative to binary L1₀ FeNi. The increase in magneto-crystalline anisotropy energy may be induced by the hybridization of Fe (Ni) 3d and B 2p orbitals. This magnitude of the resultant anisotropy is comparable to Nd-based magnets.

Intermetallic phases ripe for inclusion of boron may employ such materials as FeNi and MnAl. Interstitial boron is known to increase the magnitude of the formation enthalpy of the L1₀ phase, making it easier to form this important phase. The addition of boron may be combined with other synthesis approaches, such as rapid thermal annealing, to realize the L1₀ phase. The magnetocrystalline anisotropy of the L1₀ phase is expected to be enhanced significantly.

When boron is added to such materials as FeNi or MnNi, it can enter interstitially, which increases the magnitude of the formation enthalpy of the tetragonal L10 phase. Once these materials have been fabricated they can be moved into the L1₀ phase by annealing. The magnetocrystalline anisotropy is expected to be significantly enhanced.

In addition, adding boron may help stabilize these uniaxially symmetric high entropy materials with high magnetic anisotropy, such as the C16 high entropy boride. It is known that the C16 phase exists in Fe—B, Ni—B and Co—B phase diagrams. As an example, the C16 structure of (Fe_{0.7}Co_{0.3})₂B exhibits high magnetocrystalline anisotropy.

Challenges in stabilizing high anisotropy phases via conventional approaches may be circumvented through the use of boron, either in L1₀ phases or utilizing the configurational entropy route. In the example of L1₀ FeNi, the material has a low enthalpy and a low entropy so that its thermodynamic free energy is not low enough to be stable. Thus, this material does not form under a conventional fabrication process using materials largely at thermal equilibrium. The addition of boron may increase the enthalpy of the L1₀ phase which may make the resulting material more stable and thus more likely to form. Increasing the entropy of the material by including many elements (e.g., ≥5 elements) is another route to improve stability. Unfortunately, high entropy tends to produce phases which are not conducive to high anisotropy. Adding boron to a high entropy material leads to the formation of an ordered C16 phase.

The preliminary results above demonstrate the feasibility of achieving single-phase uniaxial symmetry high entropy materials with high magnetocrystalline anisotropy. The same procedure outlined to synthesize the Pt-based material (described below) can be used to obtain uniaxial symmetry high entropy boride materials with high magnetic anisotropy. Furthermore, the system described is consistent with criteria previously proposed for the formation of high entropy intermetallic compounds, notably having atomic size difference δᵣ=5.7% and overall electronegativity difference η=0.27, as illustrated in FIG. 4. In addition, 4 out of 5 of the 3d transition metals have the L1₀ phase with Pt in their binary phase diagrams. The application of RTA to high entropy thin films to control phase formation has not been reported before. The application of RTA is significant as the heating and cooling rates are known to be critical in determining the phase constitution of high entropy material films. Because enthalpic and entropic contributions to the free energy vary with temperature, it is possible for binary compounds to gain phase stability as the system is cooled, leading to the formation and growth of secondary phases if diffusion is not quickly suppressed. Because studies have shown boron to improve the enthalpy and magnetic anisotropy of binary L1₀ FeNi, incorporating boron into the Pt-based L1₀ system described above may further enhance its phase stability on an enthalpic front, which would combat possible phase separation, and may well enhance its magnetic anisotropy. Incorporation of boron into L1₀ materials may be done by co-sputtering with an elemental boron target in small amounts to allow interstitial occupation of the L1₀ lattice or by sputtering various targets in a sequence of layers. An alternative embodiment is to add boron to one of the metals and to fabricate a boron-doped metal target, from which the resulting material would be sputter deposited.

### High Entropy Compounds

Boron may also open routes to achieving novel high entropy structures with high magnetic anisotropy. The high entropy alloys have traditionally been multi-principal element alloys with a high configurational entropy that have attracted intense interest from researchers for their exceptional mechanical properties. These alloys were initially designed to contain ≥5 elements in equal concentration, leading to a high configurational entropy and also a high phase stability. Recent studies have demonstrated the fabrication of single-phase high entropy diborides exhibiting uniaxial crystal symmetry. These results are promising for the design of high entropy materials with high magnetic anisotropy, where boron serves to stabilize a desired structure while magnetic order and anisotropy are optimized through careful selection of the transition metal composition.

A growing area of interest is in high entropy intermetallic compounds (HEIC), which are composed of multiple sublattices, typically one of which has a high entropy configuration, and another is occupied by a single element. This opens a way for achieving the desired symmetries in high entropy systems. Single-phase HEIC have been reported recently and have been shown to exhibit exceptional properties such as superconductivity.

For the design of HEICs, the high entropy sublattice composition should satisfy the traditional high entropy design criteria related to atomic size difference and enthalpy of mixing, while also having mutually low enthalpies of formation in the desired structure with the pure sublattice element.

The expansion of material design into the high entropy composition space has allowed the discovery of numerous novel material phases with exceptional properties. High entropy materials are ideally suited to explore novel high anisotropy phases. Since the anisotropy of transition metal alloys is determined to first order by the Fermi energy, under a rigid band model the anisotropy is tunable through changes in composition which alter the effective valence electron number. High entropy materials, which contain many elements, provide unique freedom to tune material properties while maintaining control over the effective valence electron number and anisotropy. Due to the strong enthalpies and high atomic size difference of boron with the transition metals, it may be incorporated in high entropy systems to stabilize noncubic structures that give rise to uniaxial magnetic anisotropy, such as the C16 tetragonal phase. Then, the transition metal sublattice composition can be altered to search a wide range of effective valence electron numbers for an optimal magnetic anisotropy which may not be accessible in binary or ternary borides.

An example high entropy diboride is (HfZrTaCrTi)B₂ which forms a single hexagonal C32 phase. The C32 structure is a hexagonal structure where the transition metal occupies the conventional hexagonal lattice points while boron forms graphite-like hexagonal sheets which sit midway between the basal planes formed by the transition metal. Here, boron exclusively occupies a single sublattice, acting as an anchor for the C32 structure. Boron is a good element for forming HEICs due to its strong enthalpies with most transition metals. Furthermore, the materials generally exhibit exceptional mechanical and resistance properties as a result of their compositional complexity. In addition to satisfying the atomic size criteria (boron has a large atomic size difference with the transition metals), the choice of elements is motivated by the fact that each transition metal forms a C32 phase with B in their binary phase diagram. While the C32 phase may not appear in the bulk Fe—B, Co—B and Ni—B phase diagrams, it exists as a metastable ferromagnetic phase for both Fe—B and Mn—B. Thus, there is the potential to achieve ferromagnetic order in a high entropy diboride by incorporating these elements. This reasoning may be extended to predict the stability of other high entropy borides. An example of particular interest is the tetragonal C16 structure with 33 at. % B which has a high entropy phase with the potential to be stable and also to exhibit high magnetic anisotropy. This structure is found in the phase diagrams of Fe—B, Co—B, and Ni—B, which is a good indication that a high entropy C16 phase containing the ferromagnetic transition metals could form. Furthermore, this structure is known to exhibit high magnetocrystalline anisotropy in the system (Fe_{0.7}Co_{0.3})₂B. Therefore, the C16 high entropy boride may be the most promising for achieving rare-earth free high magnetic anisotropy phase with the enhanced phase stability, mechanical properties, and resistances inherent in high entropy materials. Transition-metal borides already display excellent mechanical properties, so getting them to also have high magnetocrystalline anisotropy merely compounds the interest in these materials.

Example High Entropy Material: Sputtered (FeCoNiMnCu)_{0.55}Pt_{0.45}

An example study into high entropy materials with strong magnetic anisotropy has yielded Fe—Co—Ni—Mn—Cu—Pt films with a single L1₀ phase. In an embodiment, a composite target of the transition metals may be employed along with a separate Pt target. In this example, films with a nominal composition of (FeCoNiMnCu)_{0.55}Pt_{0.45} were grown by co-sputtering of elemental Fe, Co, Ni, Mn, Cu, and Pt targets onto thermally oxidized SiO₂/Si(100) substrates, and then treated by rapid thermal annealing (RTA) to achieve L1₀ ordering. Before deposition, the SiO₂/Si substrate was cleaned in 3 consecutive ultrasonic baths of acetone, isopropanol, and de-ionized water for 10 minutes each, all followed by N₂ blow-dry. Films were grown via DC magnetron sputtering at room temperature in an ultrahigh vacuum chamber with a base pressure <1×10⁻⁷ Torr. An Argon working pressure of 2 mTorr was used during sputtering. The DC sputtering powers for the Fe, Co, Ni, Mn, Cu, and Pt targets were 35 W, 30 W, 28 W, 20 W, 13 W and 70 W, respectively. RTA was performed in a vacuum chamber at pressure <1×10⁻⁶ Torr equipped with a halogen light heating source. Most of the examples presented here were loaded at room temperature, then exposed to the heating light source during which the temperature is ramped over a 60 second period up to a nominal temperature of 600° C. measured via thermocouple at the heater. The thermocouple is not attached directly to the sample due to the difficulty in achieving a repeatable and reliable temperature measurement in that fashion. The peak temperature of the sample itself is not known precisely due to the difficulties of accurately and repeatedly measuring the sample temperature itself while undergoing RTA. In an embodiment, the heating source is directed to the side of the substrate which has the film. In a preferred embodiment, the heating source is directed to the side of the substrate which does not have the film. In an embodiment, after the total anneal period (60 seconds in most of the examples presented in this disclosure, though shorter or longer times are also possible), the sample may be removed from the light exposure area and transferred over 1-2 seconds to an adjacent load-lock chamber which is immediately vented with N₂. In an embodiment, the heating element may be turned off and the sample allowed to cool without moving to an adjacent chamber. Once the sample has cooled to an adequate temperature (e.g., 20-80° C., cool enough to not be damaged when being removed from the tool, or cool enough not to be a danger to a user), the tool may be opened to remove the sample. In an embodiment, the load-lock pressure may reach 1 atm in a period of approximately 2 minutes, after which the sample may be removed from the chamber and placed in contact with a metal platform to bring it to room temperature under ambient conditions.

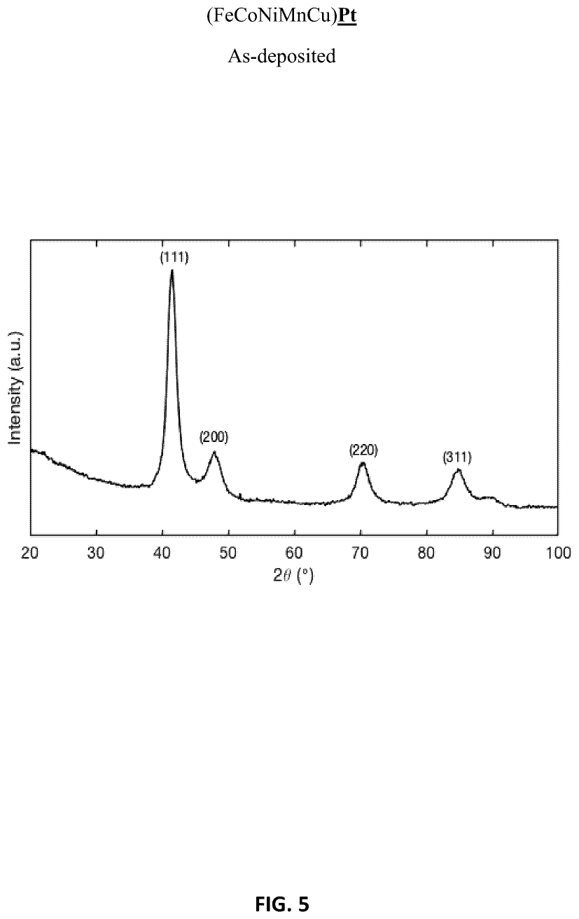

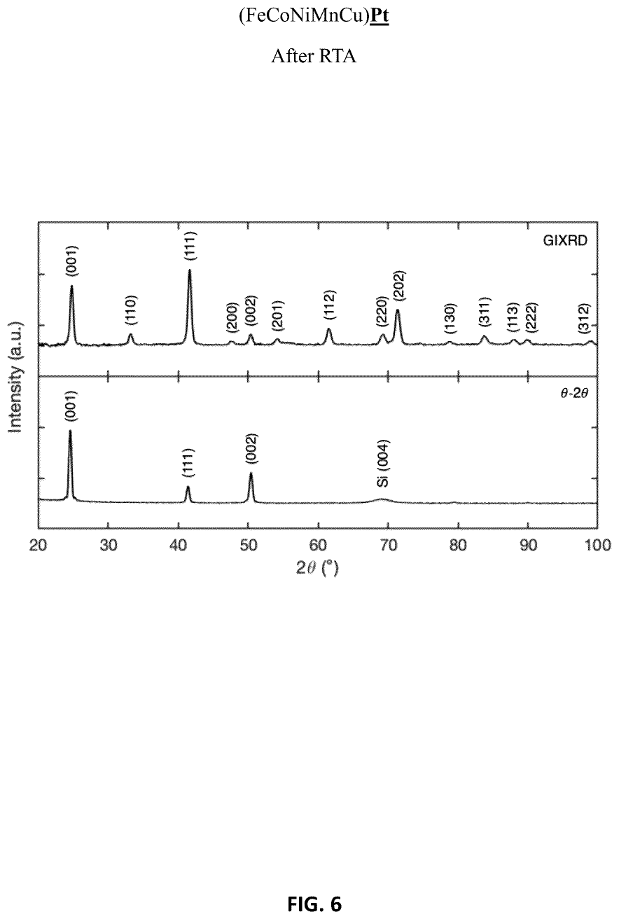

As noted above, following the deposition, the films were treated by a rapid thermal anneal (RTA) to achieve the desired L1₀ ordering. Grazing-incidence x-ray diffraction (GIXRD) was measured on 20 nm thick films. FIG. 5 shows the GIXRD scan of an as-deposited Fe—Co—Ni—Mn—Cu—Pt film exhibiting the A1 phase. The same film after rapid thermal annealing (RTA) is illustrated in FIG. 6, which shows the L1₀ phase. As-grown films show a cubic A1 structure indicating chemical disorder. After annealing, GIXRD shows a pattern consistent with L1₀ chemical ordering. There are no detectable secondary peaks, indicating the films are primarily of a single crystalline phase with L1₀ structure. The crystalline c-axis length is estimated at c=3.598 Å (0.3598 nm) from the (001) and (002) peaks and the a-axis length is estimated at a=3.829 Å (0.3829 nm) from the (110), (200), (220), and (130) peaks, giving a c/a ratio of 0.94. Other physical vapor deposition methods may also be used, as is apparent to those of ordinary skill in the art.

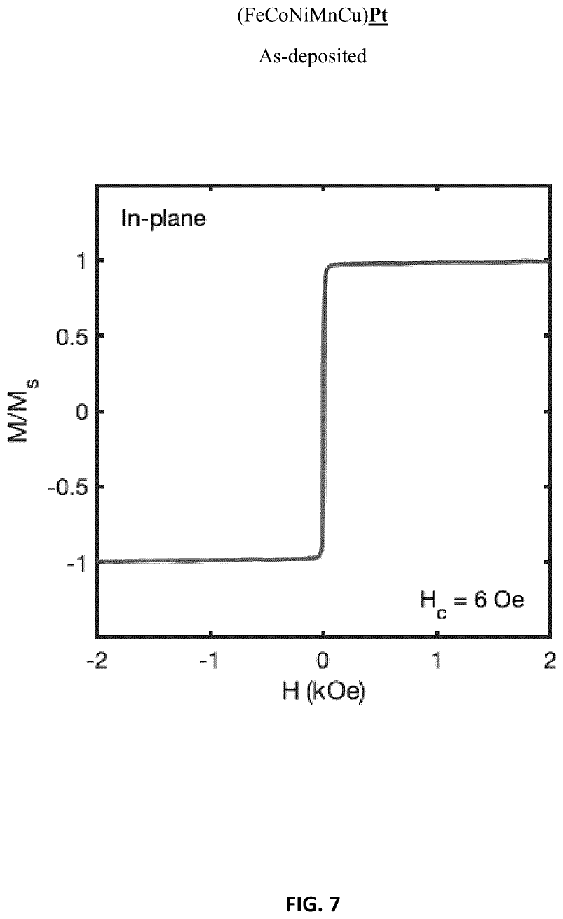

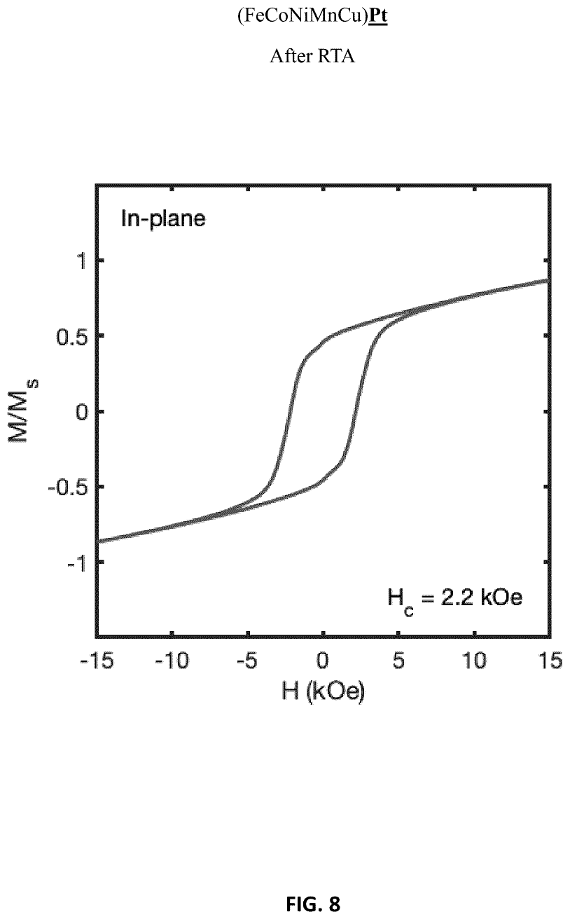

The magnetic properties of the (FeCoNiMnCu)_{0.55}Pt_{0.45} films were measured at room temperature using a vibrating sample magnetometer (VSM). FIG. 7 illustrates the hysteresis loop of as-deposited Fe—Co—Ni—Mn—Cu—Pt films with a low coercivity. FIG. 8 shows the hysteresis loop of the same film after RTA (60 s anneal with TC setpoint at 600° C.) with a high coercivity. The as-deposited films with cubic structure possess low coercivity (0.006 kOe), while the post-RTA film exhibits a high coercivity of ~2.2 kOe (≈172 kA/m) measured in-plane, indicating a substantial increase in the magnetic anisotropy, coincident with the formation of the L1₀ phase.

As an alternative design, multilayer structures may be deposited by alternating between two sputtering targets. Each layer of the structure is approximately 1 atomic layer thick (thus approximately 0.2 nm). A single atomic layer of FeCoNiMnCu may be deposited by sputtering one target, followed by a single atomic layer of Pt by sputtering a second target. By continuing to grow using this alternating structure a thin film of [(FeCoNiMnCu)Pt]₄₀ of the requisite thickness may be deposited. After the full structure has been grown, the sample may receive an RTA treatment. These films exhibited comparable crystalline and magnetic properties to the co-sputtered samples.

While high anisotropy L1₀ alloys based on Pt and Pd are poor choices for scaling to large scale production or for bulk permanent magnets because of the high prices of platinum and palladium, these materials, or other noble-metal or post-transition metals, may be employed for use in thin films. One application of such thin film materials is for magnetic recording.

Example High Entropy Compounds without Boron

FeCoNiMnCu films were deposited by DC magnetron sputtering of a homemade powder mosaic Fe—Co—Ni—Mn—Cu target. The target was formed by cold-pressing a mixture of elemental powders. The purities for Fe, Co, Ni, Mn, and Cu powders were 99.9%, 99.8%, 99.9%, 99.6%, and 99.9%, respectively, with particle size <10 μm. The powders were mixed in an equimolar ratio, and the mixture was uniaxially pressed with 50 metric tons onto a Cu backing plate, forming a target 2″ in diameter and ⅛″ thick. In one embodiment the (FeCoNiMnCu)Pt films were deposited by co-sputtering the composite FeCoNiMnCu target and a Pt target. In another embodiment the (FeCoNiMnCu)Pt films were deposited by co-sputtering of elemental Fe, Co, Ni, Mn, Cu, and Pt targets.

Films were deposited onto thermally oxidized Si(100)/SiO₂ substrate with 200 nm thick amorphous SiO₂ layer. FeCoNiMnCu films were grown with thicknesses of 13 nm and 50 nm, and the (FeCoNiMnCu)Pt films were grown to 20 nm. FeCoNiMnCu films were sputtered at substrate temperatures Ts=20, 350, 500, 600, and 700° C. while the (FeCoNiMnCu)Pt films were sputtered at room-temperature only. The films were capped with 2-4 nm of Ta or Ti to prevent oxidation. The Ar working pressure and sputtering power for deposition of the FeCoNiMnCu films was 2.5 mTorr and 50 W, respectively. For (FeCoNiMnCu)Pt films, the working pressure was 2 mTorr and the sputtering powers were 35 W, 30 W, 28 W, 20 W, 13 W, and 70 W for Fe, Co, Ni, Mn, Cu, and Pt targets, respectively. The FeCoNiMnCu films sputtered above room-temperature were allowed to cool for approximately 1 hr in 30 mTorr of Ar before deposition of the capping layer to minimize interdiffusion. The sputtered films in this example were treated with rapid thermal annealing (RTA) at a nominal (i.e. thermocouple measurement on glass between the heater and the sample) temperature of 600° C. for times ranging from 10 s to 60 s. RTA was performed in a vacuum chamber with a base pressure <1×10⁻⁷ Torr. During RTA, the sample is transferred from an adjacent load-lock chamber at vacuum into the main chamber where it is placed directly under a heating lamp for the designated annealing time. The nominal annealing temperature is set via a shielded thermocouple located near the heating lamp. After the annealing time, the sample is removed from the exposure area and transferred back to the load-lock, which is subsequently vented with N₂ and brought to atmospheric pressure over a period of 1-2 minutes, during which the sample is cooled to room-temperature.

Crystal phase analysis was performed using grazing incidence X-ray diffraction (GIXRD) with Cu K_{α} wavelength. Magnetic measurements were performed using vibrating sample magnetometer (VSM) and superconducting quantum interference device (SQUID). Surface topography was imaged using atomic force microscopy (AFM) and scanning electron microscopy (SEM). Energy-dispersive X-ray microanalysis (EDX) was performed to analyze chemical composition of the films. EDX analysis showed all elements to be within ±5 at. % of the stated composition.

### HEA Example Results

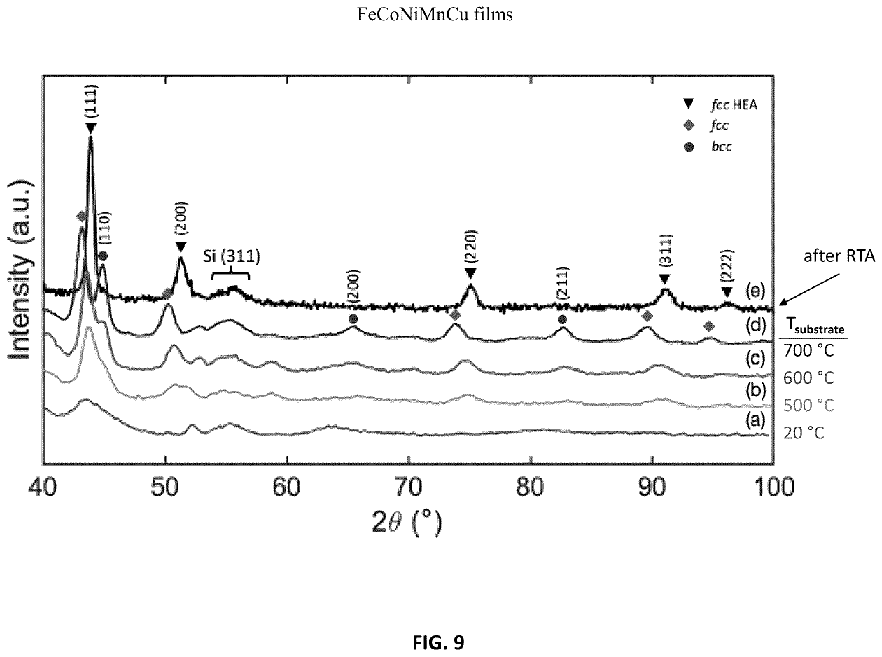

FIG. 9 shows the grazing incidence X-ray diffraction scans (ω=1°) of the 50 nm FeCoNiMnCu films for various substrate temperatures and after RTA for 30 s. The films were sputtered at various temperatures from (a) room-temperature, (b) 500° C., (c) 600° C., (d) 700° C. and (e) after RTA for 30 s. The films which were annealed were those deposited at room temperature up to 350° C. The films deposited at 500° C. and above were already crystallized during deposition, albeit into multiple phases.

The films sputtered at room-temperature show few peaks, suggesting poor crystallinity in the as-grown state. At substrate temperatures of 500° C. and above, the films show phase separation of an fcc and bcc. At Ts=700° C., the lattice parameter of the fcc and bcc phases reach 3.63 Å and 2.86 Å, respectively, which are consistent with a Cu-rich fcc and Fe-rich bcc phase, driven by the positive binary ΔHₘᵢₓ between Cu and the remaining elements, which is largest for Fe—Cu.

Alternatively, the film sputtered at Ts=350° C. with post-deposition RTA at 600° C. for 30 s shows single-phase fcc pattern consisting of (111), (200), (220) and (311) peaks. This is in agreement with previous reports of bulk FeCoNiMnCu solid-solutions and the empirical phase formation rule that 3d transition metal HEA solid-solutions with valence electron concentration (VEC)>8 exhibitfcc structure. The formation of single-phase fcc microstructure in the RTA film as opposed to multi-phase fcc+bcc demonstrates the advantage of rapid heating and cooling rates in suppressing formation of secondary phases, since the magnitude of the entropic term in the free energy decreases with temperature, promoting secondary phase formation at intermediate temperatures.

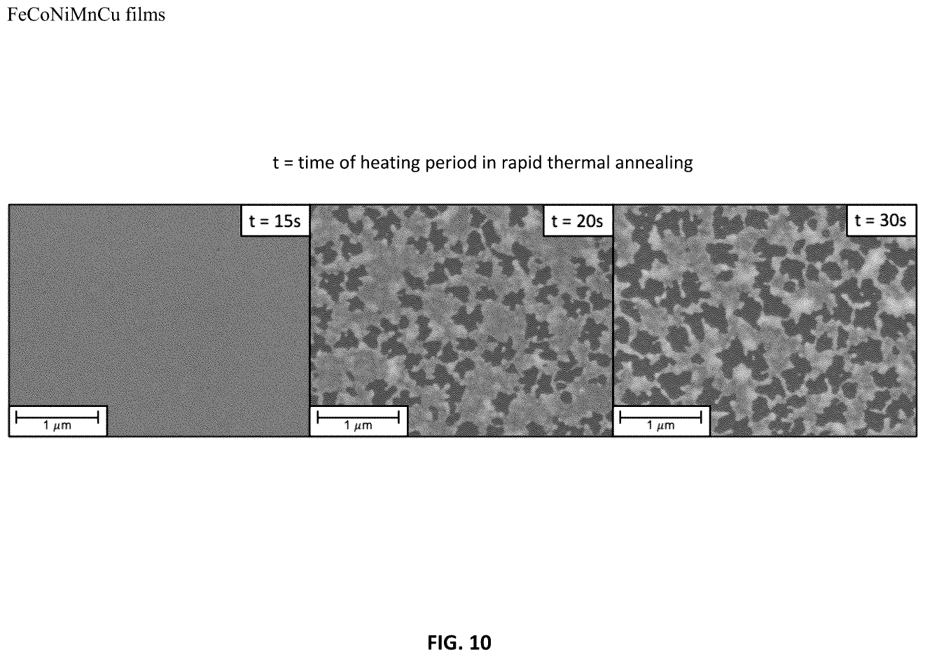

The film surface morphology was probed using scanning electron microscopy (SEM). Prolonged rapid thermal annealing of FeCoNiMnCu films on Si/SiO₂ substrate leads to dewetting. FIG. 10 shows the SEM images of a 13 nm thick film surface for increasing RTA time for an example film deposited at 350° C. The film remains smooth and continuous up to 15 s. After 20 s RTA, SEM image shows void formation in the film.

The as-grown films have a saturation magnetization Mₛ≈70 emu/g, which is substantially higher than previous reports of Mₛ of bulk equiatomic FeCoNiMnCu systems, which range from 20-40 emu/g. Films treated with RTA for 30 s show no significant change in Mₛ.

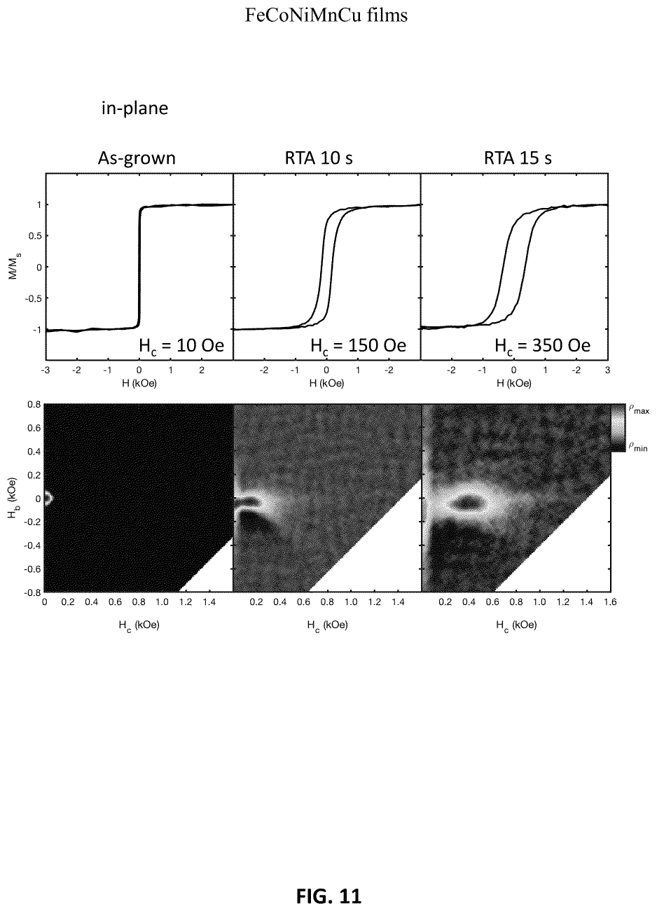

To observe the change in reversal behavior during RTA, first-order reversal curve (FORC) analysis of films was performed after different annealing times for the in-plane geometry. The FORC distribution and corresponding hysteresis loops are shown in FIG. 11. In-plane hysteresis loop and FORC distribution of FeCoNiMnCu films as-grown (left) and after RTA for 10 sec (middle) and 15 sec (right) are illustrated. The as-grown films are magnetically soft and the FORC distribution contains a single peak near H_{c}=0. After RTA for 10 s, H_{c} increases to 170 Oe and the FORC distribution shows a separate peak centered around H_{c}=150 Oe alongside the low H_{c}peak. Additionally, the low H_{c} feature becomes more spread along the H_{b} axis, representing a reversible component of the magnetization, indicating thermal or anisotropic demagnetization effects. After 15 s of RTA, H_{c} reaches 350 Oe, and the high H_{c} peak becomes more separated from the low H_{c} feature and spread along the H_{c} axis. Meanwhile, the low H_{c} feature becomes more spread along the H_{b} axis, forming the “reversible ridge.” Increasing the RTA time to 30 s, H_{c} increases to 390 Oe and the prior trends continue. By numerical integration of the FORC distribution around the high H_{c} feature, it is determined that this feature is associated with 60% of the magnetization. Therefore, the RTA leads to semi-hard switching behavior in a large fraction of the film, while part of the film remains magnetically soft.

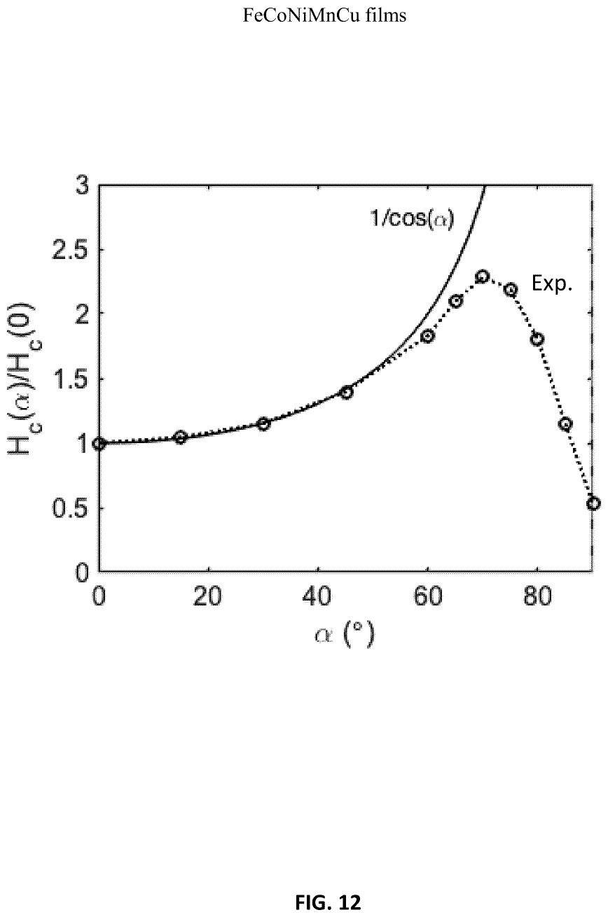

The increase of coercivity coincides with multiple changes in film microstructure after annealing, specifically the crystallization and void formation. The crystallization of the film is expected to generate magnetocrystalline anisotropy, as well as create grain boundaries between the crystallized phase and the parent phase which serve as domain wall pinning sites. The effect of void formation is to create pinning sites, and to eventually reduce the probability of domain wall propagation across isolated islands. By measuring the angular variation in coercivity, further insight into the coercivity mechanism may be gained. FIG. 12 shows the dependence of the normalized coercivity H_{c}(α)/H_{c}(0) on the angle α between the measurement direction and film surface for an example FeCoNiMnCu film after RTA. H_{c}(0) is the in-plane coercivity. The coercivity follows the Kondorsky-like (cos α)⁻¹ dependence at low angles, revealing the pinning-controlled coercivity mechanism for magnetization reversal along in-plane directions. The peak and subsequent decrease of H_{c} at higher angles signals the transition to coherent rotation or nucleation-controlled coercivity.

While the Mₛ and H_{c} reported here for examples of sputtered and rapid thermally annealed FeCoNiMnCu films are higher than previously reported bulk systems, the coercivity still has room for further improvement, due to the relatively low anisotropy of the cubic phase. Achieving optimal magnetic anisotropy and high coercivity in HEAs requires composition choices which facilitate low-symmetry chemical order and crystal structure in addition to high entropy. To apply the previously proposed design criteria for single-phase HEIs in the fabrication of a high magnetic anisotropy phase, 45 at. % Pt was added to the FeCoNiMnCu system to facilitate L1₀ ordering.

### Adding Platinum (Pt) to Films

Pt-based L1₀ structure is a good testbed for fabrication of high entropy intermetallic with high anisotropy, since Fe, Co, Ni, and Mn each form a stable binary L1₀ structure with Pt, therefore they are all energetically inclined to order in such a way with Pt. Pt forms the “skeleton” of this structure. At the same time, a solid-solution of FeCoNiMnCu has a modest total mixing enthalpy and high entropy, allowing the elements to mix comfortably on the sublattice opposite of Pt, rather than separate to other binary phases. This composition also exists in the range of electronegativity and atomic size difference which is proposed to exhibit the stable single-phase high entropy intermetallics. FIG. 3 and FIG. 4 illustrate why platinum (or another metal like aluminum) may help improve the magnetic properties of these films. FIG. 3 illustrates a hypothetical tetragonal crystalline structure with another metal (Pt in this example) at the ends and intermixed with FeCoNiMnCu layers. FIG. 4 shows the atomic radius dispersivity as a function of the overall electronegativity difference. The (FeCoNiMnCu)Pt film properties are noted by the star.

FIG. 6 shows the grazing incidence X-ray diffraction (GIXRD) and θ-2θ (1° ω-offset) scans for 20 nm (FeCoNiMnCu)Pt films after RTA for 60 s with a thermocouple setpoint of 600° C. The as-grown films are fcc with a lattice parameter of 3.80 Å. After RTA, L1₀ ordering of Pt and FeCoNiMnCu is observed, indicated by the emergence of forbidden peaks and peak-splitting due to the tetragonal symmetry. The lattice parameters of the L1₀ phase extracted from (001) and (110) peaks are c=3.60 Å and a 3.83 Å. No additional phase peaks are detected, indicating that the 3d TMs primarily order with Pt into the L1₀ structure. An L1₀ order parameter for (001)-oriented grains of S=0.8 is estimated from the ratio of integrated intensities of the superlattice and fundamental peaks according to

$$S = \sqrt{\frac{{( {I}_{001} / {I}_{002} )}_{exp .}}{{( {I}_{001} / {I}_{002} )}_{calc .}}}$$

where the numerator includes the intensities extracted from the θ-2θ XRD data, and the denominator includes the calculated intensities. An example of such structure is illustrated in FIG. 3.

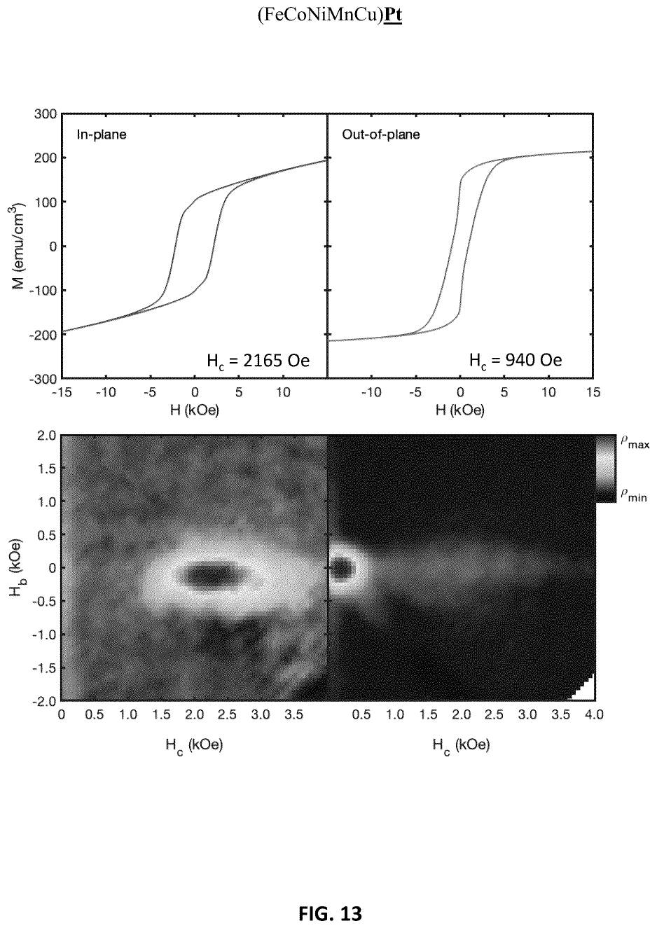

The in-plane (left side) and out-of-plane (right side) hysteresis loops are shown in FIG. 13 along with the corresponding FORC distributions on the bottom of the figure. The as-grown films are magnetically soft with in-plane anisotropy. After a 60 second RTA, He increases to 2.16 kOe for the in-plane loop and 0.94 kOe out-of-plane. The films show perpendicular anisotropy and the effective uniaxial anisotropy constant, extracted from the area between the magnetization curves for the in-plane and out-of-plane directions, is 2×10⁶ erg/cm³. Integrating the high H_{c} feature of the in-plane FORC distribution returns 45% of the magnetization, while the remaining magnetization exists in the reversible ridge, which partially represents the magnetization reversal along the hard-axis of the (001)-textured grains.

This disclosure demonstrates fabrication of single-phase high entropy alloy FeCoNiMnCu thin films by sputtering of a mixed powder target and RTA. The FeCoNiMnCu films show a sizeable coercivity increase after annealing resulting from the phase crystallization and microstructure change which strengthen the pinning of domain walls. An RTA procedure may also be applied to films with a composition of (FeCoNiMnCu)Pt and it was found that such films order into an L1₀ high entropy intermetallic phase. A very large increase in coercivity to over 2 kOe is observed, resulting from the high magnetocrystalline anisotropy of the L1₀ phase. These results show the promise in achieving single-phase high entropy thin films by application of sputtering and rapid thermal annealing, and point to the high entropy intermetallic approach as a key avenue for discovering high entropy phases which exhibit high magnetic anisotropy.

### Adding Boron to Films

FIG. 2 illustrates a crystalline structure of a prototype binary system (Fe_{0.7}C_{0.3})₂B. This figure depicts the C16 tetragonal structure at about 33 at % boron. Theory has predicted that this system may have excellent magnetic properties. Many individual metals form a tetragonal structure when mixed with 33 at. % B. On their own, for example, Fe₂B and CO₂B have a moderate “easy-plane” anisotropy which ultimately has weaker hard magnetic properties than a material with “easy-axis” anisotropy. Previous study has shown that mixing of a certain ratio of Fe and Co on the metal sub-lattice leads to a high easy-axis anisotropy, greatly improving the magnetic properties. A greater parameter space which potentially contains more optimal easy-axis anisotropy may be accessed by incorporating 4-5 elements on the metal sublattice. A phase diagram analysis of the compounds of Fe—B, Co—B, Ni—B, and Mn—B further supports this justification for adding boron to these high entropy materials to improve their magnetic properties.

### Other Results of High Entropy Material Incorporating Boron

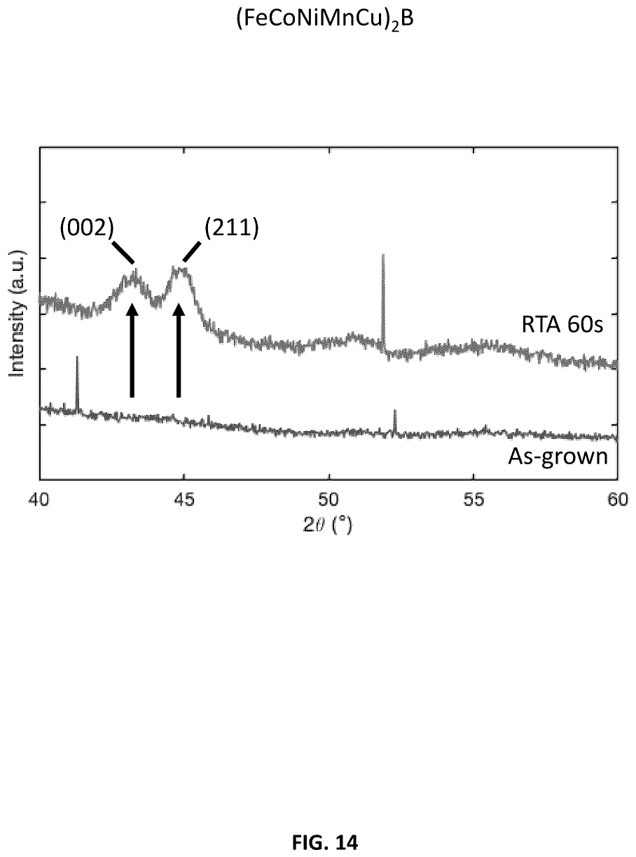

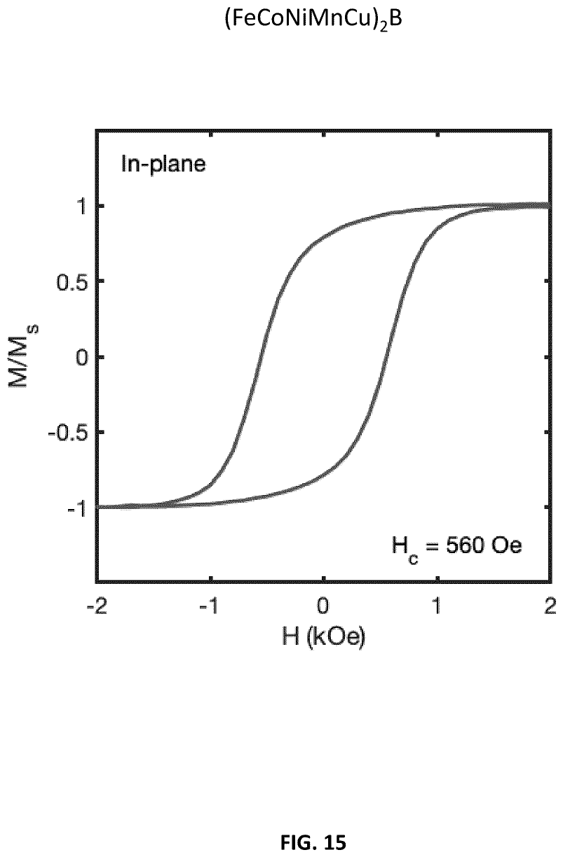

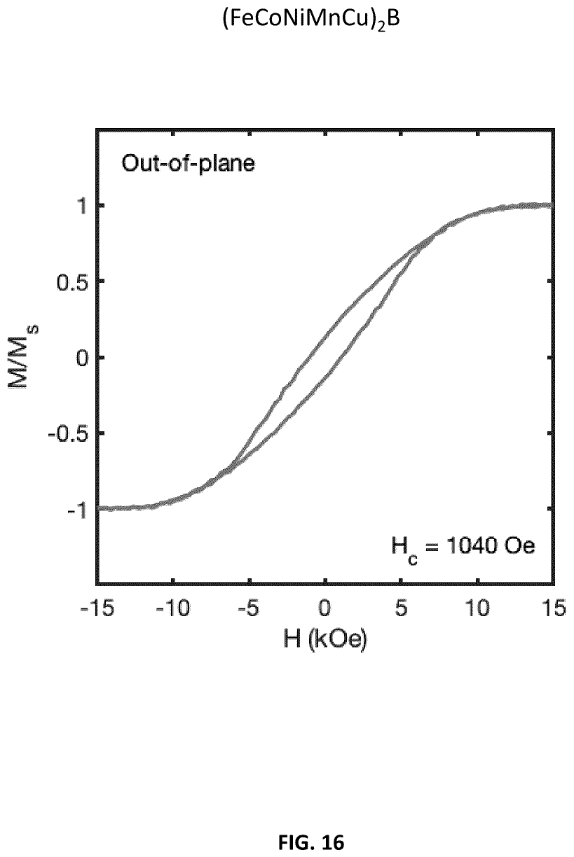

In an example, thin films with a composition of (FeCoNiMnCu)₂B were sputter-deposited as described elsewhere in this disclosure. In this example, the films were deposited using 6 targets, one for each element used, to form a multilayer structure consisting of FeCoNiMnCu and B layers. The FeCoNiMnCu layers were fixed at a thickness of 0.46 nm and deposited by co-sputtering of the Fe, Co, Ni, Mn, and Cu targets. The B layers were deposited by sputtering from an elemental B target and the thickness was varied. The FeCoNiMnCu/B bilayer deposition was repeated up to 30×. The example films were annealed in the RTA system using the same conditions (60 s exposure at a nominal temperature setpoint of 600° C.) and the coercivity was measured. These films showed a large increase in coercivity, and 2 new peaks emerge in XRD that are consistent with a C16 structure and which indicates change in crystal structure. The XRD results are shown in FIG. 14 and the coercivity results are shown in FIG. 15 and FIG. 16. Note the difference in scale of the abscissa of FIG. 16 relative to FIG. 15. Table 1, below, shows some of the anneal conditions for these films which included boron at different thicknesses. The RTA has been described elsewhere in this disclosure. The boron thickness in Table 1 was measured by etching a boron-only thin film into a stripe and then using an atomic force microscope to measure the thickness. The calculated boron deposition rate was then used to estimate the boron thickness.

TABLE 1
sputtering and annealing parameters for [FeCoNiMnCu/B]
₃₀ films with 0.46 nm FeCoNiMnCu in each bilayer repetition.

| | RTA (600° C.) | | Conventional Anneal | | |
|---|---|---|---|---|---|
| B thickness | Anneal | H_{c} | Time | Temp | H_{c} |
| (nm) | time (s) | (Oe) | (min) | (° C.) | (Oe) |
| 0.11 | 30 | 201 | 30 | 200 | 90 |
| | 60 | 553 | 60 | 700 | 315 |
| 0.13 | 30 | 445 | 30 | 200 | 90 |
| | 60 | 268 | | | |
| 0.15 | 30 | 128 | 30 | 200 | 4 |
| | 60 | 44 | 60 | 700 | 204 |

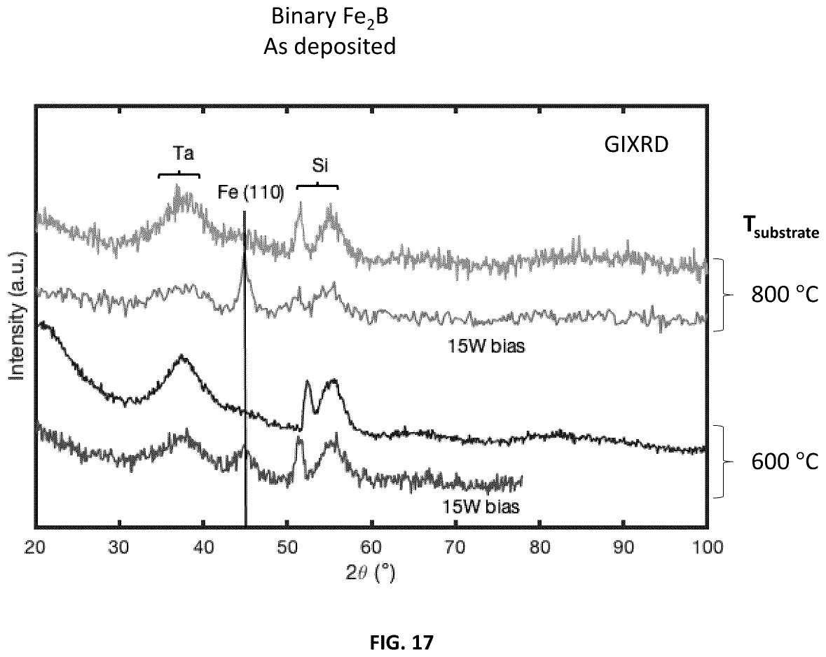

FIG. 17 shows the GIXRD results for the binary Fe₂B films. These films were deposited by co-sputtering of Fe and B targets. The substrate temperature during sputtering was varied to determine an optimal fabrication condition. Immediately after deposition, the films showed little crystalline structure, even at a deposition temperature of 800° C. In addition, various alternative approaches were attempted using substrate heating in combination with an rf voltage to bias the substrate during co-sputtering of Fe and B targets. Application of substrate bias (e.g., an rf voltage applied between the substrate and ground) during deposition led to growth of the Fe (110) peak indicating phase separation between Fe and B, while no C16 phase was detected.

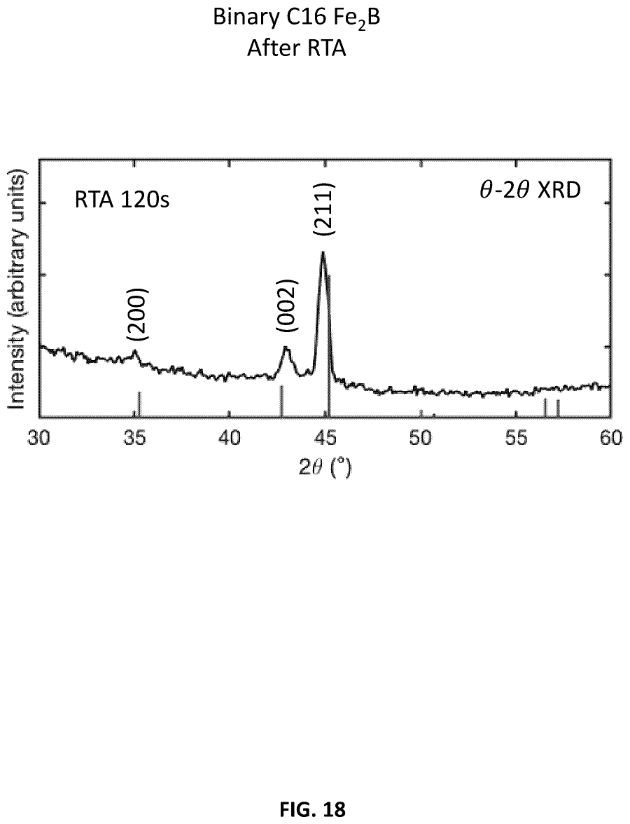

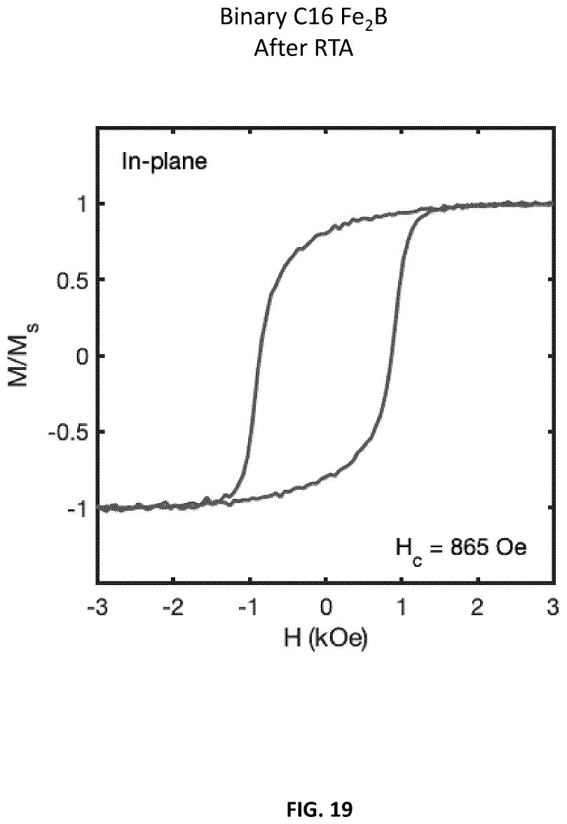

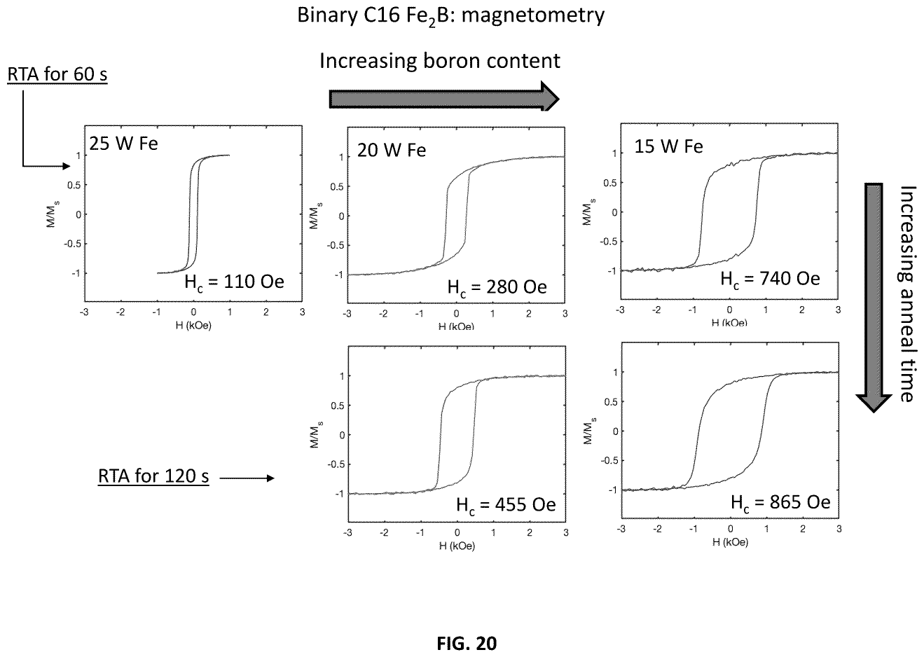

FIG. 18 shows the results of applying RTA to the Fe₂B films grown at room-temperature. Three peaks were apparent in the XRD results and are consistent with the C16 structure. The intensity and width of these peaks suggests a larger crystallite size than in the as-deposited Fe₂B films. The magnetic coercivity of this film is illustrated in FIG. 19 and demonstrates the high magnetic anisotropy associated with the tetragonal C16 phase of Fe₂B. More data on the magnetic properties are illustrated in FIG. 20. By decreasing the Fe sputtering power (while maintaining the same power on the boron sputtering target) the boron concentration in the resulting compound was increased towards the optimal 33 at %. The coervicity, H_{c}, also increases as the anneal time is increased, due to increased crystallization.

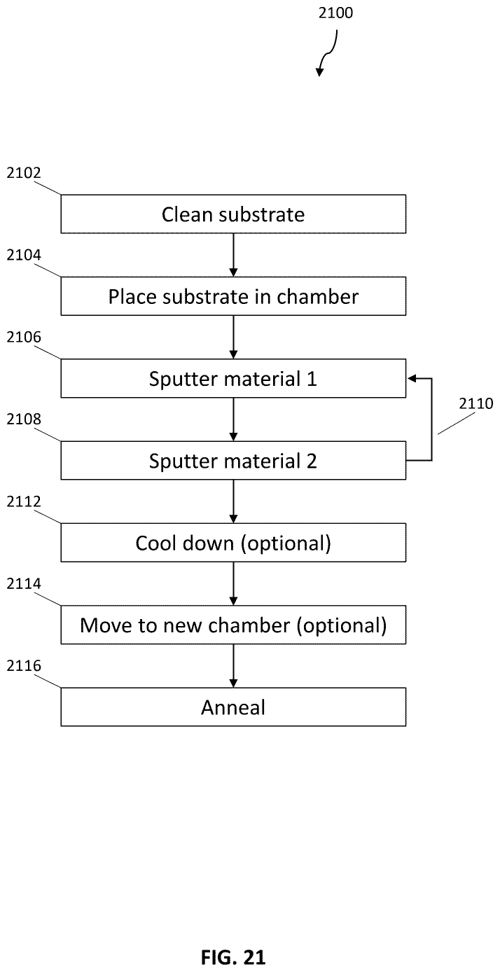

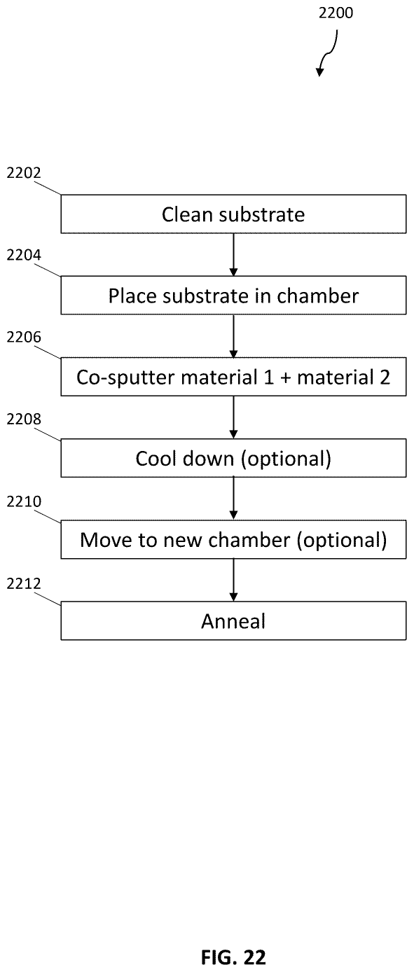

FIG. 21 and FIG. 22 illustrate two example processes for fabricating materials with high magnetic anisotropy. FIG. 21 shows an example of a process flow 2100 for sputter deposition of such a material. At step 2102, a substrate for the deposition of the material is cleaned. In an example, such a substrate may be a silicon wafer with an oxidized surface. At step 2104, the substrate may be placed in a vacuum chamber. At step 2106, a first material may be sputter-deposited on the substrate. At step 2108, a second material may be sputter-deposited on the substrate. At step 2110, this process may be repeated. Thus steps 2106 (sputter-deposition of material 1) and 2108 (sputter-deposition of material 2) may be repeated until the desired film thickness is reached. At this point the process may optionally move on to step 2112, cool down. As described elsewhere in this disclosure material 1 may comprise a multi-element material such as FeCoNiMnCu and material 2 may comprise a single element material such as boron (B) or platinum (Pt) or aluminum (Al). The thicknesses deposited in steps 2106 and 2108 need not be the same for both materials, but can be varied to achieve, for instance, a desired atomic percentage of boron in the resulting material. Material 1 may also comprise a single element or several elements. At step 2112, the sample (the substrate now coated on at least one side with the desired multi-element material) is cooled down. At step 2114, the sample may be removed from the vacuum chamber. In some embodiments, step 2114 is optional as the annealing may occur within the same vacuum chamber as the sputter deposition or be transferred to a chamber for performing the anneal but without being removed from vacuum. At step 2116, the sample is annealed, as described elsewhere in this disclosure. In an embodiment, the sample may also be flipped to allow the heating lamp to illuminate the substrate directly rather than illuminate the thin film directly.

FIG. 22 illustrates an alternative process for producing a magnet material. In this process 2200, the substrate is cleaned at step 2202, and placed in the deposition chamber at step 2204, as in process 2100. At step 2206, however, a first material and a second material are co-sputtered from at least two targets at the same time. In certain embodiments, the co-sputtering may involve more than two targets, for instance, six sputtering targets, one each of Fe, Co, Ni, Mn, Cu, and Pt or the last material may be boron, or another element. Once the desired thickness of material is achieved, at step 2208 the sample is allowed to cool down. At step 2210 the sample may optionally be removed from the chamber to facilitate transfer to an annealing tool. As noted above, in some instance, the sample may be annealed in the same chamber or may be moved to an appropriate chamber without leaving vacuum. At step 2212, the sample is annealed.

The co-sputtering process 2200 at step 2206 differs from the cycled process 2100 at steps 2106, 2108, and 2110 in that the co-sputtering process 2200 deposits material onto the substrate from at least two sputtering targets at the same time whereas the cycled process 2100 deposits from a single sputtering target at a time. It is also possible in some embodiments to combine aspects of both a co-sputtering process 2200 and a cycled process 2100. For example, one may co-sputter using two targets and then cycled sputter with a third target. The annealing step 2116 or 2212 has been detailed in other parts of this disclosure. In an embodiment, a rapid thermal annealing (RTA) tool is preferred. In another embodiment the rapid thermal annealing may take place in the same vacuum chamber as the sputter deposition or it make take place in a chamber to which the sample is transferred without breaking vacuum. The sample may be loaded or transferred into the RTA chamber. In the examples discussed above the RTA was performed in vacuum, but in an alternative embodiment the anneal may be performed in an inert gas. The sample may be rapidly heated up using lamps to a nominal temperature of 600-1000° C. with a ramp rate of ≥10° C./s. After a set time period (e.g., 10-600 sec), the heater power is cut and the sample is cooled and then removed from the RTA tool. In an embodiment, the rapid ramp to a peak temperature may also be characterized as a spike or flash anneal with only a very brief time (~0.1 s to ~10 s, typically ~1 s) at the peak temperature. In an embodiment, the time of the entire anneal may be fixed and the sample's actual temperature may continue to increase during the entire heating period until the heater is turned off. The nominal (thermocouple) temperature may be held constant, but the actual sample temperature may increase during the entire time of the anneal. In an alternative embodiment, the actual sample temperature is ramped throughout the anneal time and then cooled. In an alternative embodiment, the sample is heated to an actual peak temperature and held at the peak temperature for a set time period before the heater is turned off and the sample is allowed to cool.

Quinary (FeₓCo_{y}Ni_{z}Mn_{1-x-y-z})₂B Films

In this disclosure, 3d TMs are introduced to realize C16 phase high entropy borides and explore their properties across the composition space using a combinatorial co-sputtering method, leading to the discovery of novel quinary boride compositions with high magnetic anisotropy.

From these experimental results, it was found that quinary transitional metal borides with C16 crystal structure exhibit high magnetic anisotropy in a specific range of transition metal compositions. The compositions disclosed, and their magnetic anisotropy, may be substantially enhanced with respect to any currently known C16 phase transition metal borides. Importantly, the high anisotropy is achieved using only earth-abundant 3d metals and B, making these rare-earth-free and precious-metal-free high magnetic anisotropy materials. An example composition with high magnetic anisotropy is (Fe_{0.35}Co_{0.17}Ni_{0.17}Mn_{0.31})₂B. The magnetic properties depend on the ratio of the different metals.

Methods of forming materials as described herein may include the following steps. In one embodiment, films may be deposited by DC magnetron sputtering in an ultrahigh vacuum system with a base pressure of <1×10⁻⁷ Torr, and ideally at 1×10⁻⁸ Torr or better. Multicomponent boride films are deposited by co-sputtering of stoichiometric boride targets such as Fe₂B, Co₂B, Ni₂B, and Mn₂B onto thermally oxidized Si(100) substrates with a 200 nm thick amorphous SiO₂ layer. All depositions may be performed at room-temperature with an Ar working pressure of 5 mTorr. Films may be capped with 2.5 nm thick layer of Ta to protect from oxidation. After deposition, films may be treated with RTA in vacuum chamber with base pressure <1×10⁻⁷ Torr for 60-120 s.

In one example, films were fabricated by co-sputtering of Fe₂B, CO₂B, Ni₂B, and Mn₂B targets, where each target comprises ~33 at. % B and ~66 at. % of a transition metal. Boride films were deposited onto Si (100) substrates with 200 nm amorphous SiO₂ layer by direct-current (DC) magnetron sputtering in an ultrahigh vacuum system with a base pressure of ~1×10⁻⁸ Torr and working pressure of 5 mTorr Ar.

Sputtered films were treated with RTA in a vacuum chamber with a base pressure ~1×10⁻⁸ Torr. During RTA, the sample was transferred from an adjacent load-lock chamber under vacuum into the main chamber where it is placed directly under a heating lamp for the designated annealing time, ranging from 60 s to 120 s. The annealing temperature of 600° C. corresponds to the equilibrium temperature of the surrounding chamber environment, as set via thermocouple in contact with the lamp window, located approximately 1-2 cm from both the sample and heating filament. Subsequently, the sample was transferred back to the load-lock, which was vented with dry N₂ and brought to atmospheric pressure over a period of approximately 2 min, during which the sample is cooled to room-temperature.

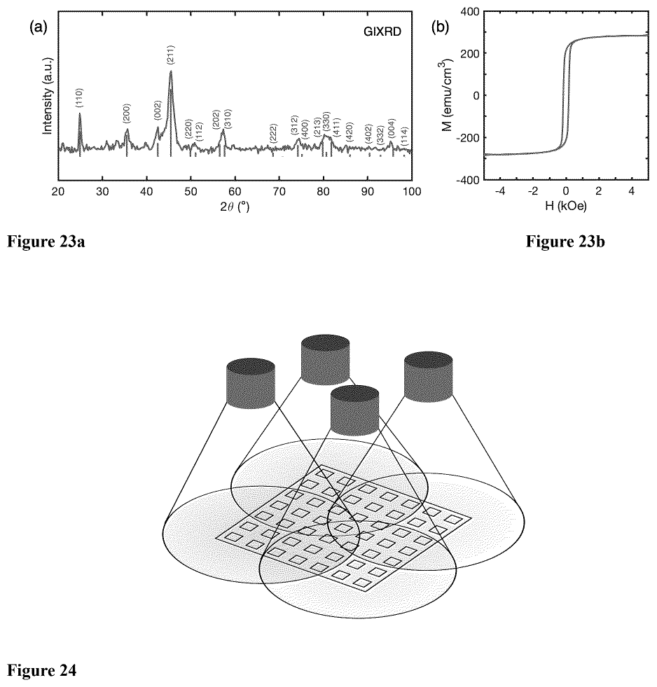

In one example, 50 nm films with a composition of (Fe_{0.30}Co_{0.23}Ni_{0.26}Mn_{0.21})₂B determined by EDX analysis were deposited onto Si/SiO₂ substrates by co-sputtering of Fe₂B, Co₂B, Ni₂B and Mn₂B targets. FIG. 23a shows the GIXRD scans (ω=10) of the films treated with RTA at 600° C. for 120 s. The films may be found to crystallize into a C16 phase with lattice parameters of α=5.05 Å and c=4.25 Å, based on the position of (002) and (211) diffraction peaks. The calculated powder diffraction pattern for a C16 structure with these lattice parameters is displayed in FIG. 23a and can be seen to well-match the measured diffraction profile, confirming C16 phase formation in the high entropy film. FIG. 23b shows the hysteresis loop of the (FeCoNiMn)₂B film measured along the in-plane direction. The film is ferromagnetic with a low Mₛ=284 emu/cm³ and a modest H_{c}=166 Oe. The low H_{c} compared with the 50 nm (Fe₁₋ₓCoₓ)₂B films suggests a relatively low anisotropy near the equimolar composition in the C16 high entropy boride.

In one example, films may be fabricated using a combinatorial deposition method. For combinatorial deposition, a 4″ diameter Si/SiO₂ wafer was masked into a 7×7 grid of 5×5 mm² cells. The Fe₂B, CO₂B, Ni₂B and Mn₂B targets may be positioned in the chamber so that they occupy corners of a square, the center of which is aligned with the center of the Si/SiO₂ substrate, as depicted in FIG. 24. The substrate was not rotated during deposition to allow the formation of a composition gradient across the film according to the cells' distance from each target. The relative positions of the sputtering targets may be permutated to produce 2 series of combinatorial films with distinct composition profiles. For Series 1, the clockwise sequence of targets was Fe₂B, Mn₂B, Ni₂B, Co₂B. For Series 2, the sequence was Fe₂B, Mn₂B, Co₂B, Ni₂B.

Two series of combinatorial samples (labeled Series 1 and Series 2) were deposited by combinatorial sputtering as described and treated with RTA at 600° C. for 60 s. Samples are labeled by their series and position in the grid (rows A-G and columns 1-7). The transition metal compositions for all samples were determined by EDX and are listed in Table 2. The concentrations of TMs range from ~10% to ~50% of the total TM compositions for each TM.

TABLE 2
for sample compositions:

| | 1 | 2 | 3 | 4 |
|---|---|---|---|---|
| | Series 1 | | | |
| A | (Fe_{0.17}Co_{0.13}Ni_{0.22}Mn_{0.48})₂B | (Fe_{0.22}Co_{0.13}Ni_{0.26}Mn_{0.39})₂B | (Fe_{0.18}Co_{0.18}Ni_{0.27}Mn_{0.36})₂B | (Fe_{0.14}Co_{0.19}Ni_{0.33}Mn_{0.32})₂B |
| B | (Fe_{0.26}Co_{0.13}Ni_{0.22}Mn_{0.39})₂B | (Fe_{0.27}Co_{0.14}Ni_{0.23}Mn_{0.36})₂B | (Fe_{0.26}Co_{0.18}Ni_{0.26}Mn_{0.29})₂B | (Fe_{0.19}Co_{0.19}Ni_{0.33}Mn_{0.33})₂B |
| C | (Fe_{0.29}Co_{0.14}Ni_{0.19}Mn_{0.38})₂B | (Fe_{0.26}Co_{0.22}Ni_{0.22}Mn_{0.30})₂B | (Fe_{0.23}Co_{0.23}Ni_{0.23}Mn_{0.32})₂B | (Fe_{0.21}Co_{0.21}Ni_{0.32}Mn_{0.29})₂B |
| D | (Fe_{0.36}Co_{0.18}Ni_{0.14}Mn_{0.32})₂B | (Fe_{0.27}Co_{0.18}Ni_{0.18}Mn_{0.36})₂B | (Fe_{0.24}Co_{0.24}Ni_{0.24}Mn_{0.29})₂B | (Fe_{0.23}Co_{0.23}Ni_{0.32}Mn_{0.27})₂B |
| E | (Fe_{0.35}Co_{0.17}Ni_{0.17}Mn_{0.31})₂B | (Fe_{0.35}Co_{0.22}Ni_{0.17}Mn_{0.26})₂B | (Fe_{0.38}Co_{0.24}Ni_{0.14}Mn_{0.24})₂B | (Fe_{0.25}Co_{0.29}Ni_{0.25}Mn_{0.20})₂B |
| F | (Fe_{0.41}Co_{0.18}Ni_{0.14}Mn_{0.27})₂B | (Fe_{0.39}Co_{0.26}Ni_{0.13}Mn_{0.22})₂B | (Fe_{0.38}Co_{0.24}Ni_{0.19}Mn_{0.19})₂B | (Fe_{0.28}Co_{0.36}Ni_{0.18}Mn_{0.15})₂B |
| G | (Fe_{0.50}Co_{0.18}Ni_{0.09}Mn_{0.23})₂B | (Fe_{0.44}Co_{0.24}Ni_{0.12}Mn_{0.20})₂B | (Fe_{0.40}Co_{0.30}Ni_{0.13}Mn_{0.17})₂B | (Fe_{0.33}Co_{0.33}Ni_{0.17}Mn_{0.14})₂B |
| | Series 2 | | | |
| A | (Fe_{0.23}Co_{0.16}Ni_{0.10}Mn_{0.52})₂B | (Fe_{0.22}Co_{0.25}Ni_{0.09}Mn_{0.44})₂B | (Fe_{0.22}Co_{0.28}Ni_{0.12}Mn_{0.38})₂B | (Fe_{0.19}Co_{0.32}Ni_{0.16}Mn_{0.32})₂B |
| B | (Fe_{0.29}Co_{0.18}Ni_{0.12}Mn_{0.41})₂B | (Fe_{0.27}Co_{0.23}Ni_{0.10}Mn_{0.40})₂B | (Fe_{0.20}Co_{0.30}Ni_{0.17}Mn_{0.33})₂B | (Fe_{0.22}Co_{0.26}Ni_{0.19}Mn_{0.33})₂B |
| C | (Fe_{0.32}Co_{0.13}Ni_{0.10}Mn_{0.45})₂B | (Fe_{0.28}Co_{0.21}Ni_{0.14}Mn_{0.38})₂B | (Fe_{0.27}Co_{0.27}Ni_{0.13}Mn_{0.33})₂B | (Fe_{0.25}Co_{0.29}Ni_{0.18}Mn_{0.29})₂B |
| D | (Fe_{0.39}Co_{0.16}Ni_{0.13}Mn_{0.32})₂B | (Fe_{0.35}Co_{0.16}Ni_{0.16}Mn_{0.32})₂B | (Fe_{0.31}Co_{0.17}Ni_{0.21}Mn_{0.31})₂B | (Fe_{0.27}Co_{0.23}Ni_{0.23}Mn_{0.27})₂B |
| E | (Fe_{0.45}Co_{0.13}Ni_{0.16}Mn_{0.26})₂B | (Fe_{0.39}Co_{0.18}Ni_{0.18}Mn_{0.25})₂B | (Fe_{0.38}Co_{0.17}Ni_{0.21}Mn_{0.24})₂B | (Fe_{0.30}Co_{0.23}Ni_{0.27}Mn_{0.20})₂B |
| F | (Fe_{0.48}Co_{0.12}Ni_{0.18}Mn_{0.21})₂B | (Fe_{0.45}Co_{0.16}Ni_{0.19}Mn_{0.19})₂B | (Fe_{0.44}Co_{0.15}Ni_{0.22}Mn_{0.19})₂B | (Fe_{0.38}Co_{0.19}Ni_{0.27}Mn_{0.15})₂B |
| G | (Fe_{0.53}Co_{0.09}Ni_{0.19}Mn_{0.19})₂B | (Fe_{0.54}Co_{0.11}Ni_{0.18}Mn_{0.18})₂B | (Fe_{0.43}Co_{0.18}Ni_{0.25}Mn_{0.14})₂B | (Fe_{0.41}Co_{0.14}Ni_{0.31}Mn_{0.14})₂B |

| | 5 | 6 | 7 |
|---|---|---|---|
| | Series 1 | | |
| A | (Fe_{0.13}Co_{0.22}Ni_{0.39}Mn_{0.26})₂B | (Fe_{0.12}Co_{0.21}Ni_{0.46}Mn_{0.21})₂B | (Fe_{0.12}Co_{0.24}Ni_{0.48}Mn_{0.16})₂B |
| B | (Fe_{0.17}Co_{0.26}Ni_{0.39}Mn_{0.17})₂B | (Fe_{0.13}Co_{0.26}Ni_{0.39}Mn_{0.22})₂B | (Fe_{0.12}Co_{0.29}Ni_{0.42}Mn_{0.17})₂B |
| C | (Fe_{0.14}Co_{0.24}Ni_{0.38}Mn_{0.24})₂B | (Fe_{0.18}Co_{0.27}Ni_{0.36}Mn_{0.18})₂B | (Fe_{0.14}Co_{0.33}Ni_{0.38}Mn_{0.14})₂B |
| D | (Fe_{0.18}Co_{0.27}Ni_{0.32}Mn_{0.23})₂B | (Fe_{0.17}Co_{0.30}Ni_{0.30}Mn_{0.22})₂B | (Fe_{0.14}Co_{0.32}Ni_{0.36}Mn_{0.18})₂B |
| E | (Fe_{0.25}Co_{0.35}Ni_{0.20}Mn_{0.20})₂B | (Fe_{0.21}Co_{0.37}Ni_{0.29}Mn_{0.12})₂B | (Fe_{0.17}Co_{0.43}Ni_{0.26}Mn_{0.13})₂B |
| F | (Fe_{0.26}Co_{0.39}Ni_{0.22}Mn_{0.13})₂B | (Fe_{0.25}Co_{0.42}Ni_{0.21}Mn_{0.12})₂B | (Fe_{0.20}Co_{0.48}Ni_{0.24}Mn_{0.08})₂B |
| G | (Fe_{0.28}Co_{0.40}Ni_{0.20}Mn_{0.12})₂B | (Fe_{0.24}Co_{0.52}Ni_{0.14}Mn_{0.10})₂B | (Fe_{0.20}Co_{0.52}Ni_{0.20}Mn_{0.08})₂B |
| | Series 2 | | |
| A | (Fe_{0.14}Co_{0.38}Ni_{0.14}Mn_{0.34})₂B | (Fe_{0.12}Co_{0.44}Ni_{0.19}Mn_{0.25})₂B | (Fe_{0.09}Co_{0.50}Ni_{0.19}Mn_{0.22})₂B |
| B | (Fe_{0.18}Co_{0.36}Ni_{0.14}Mn_{0.32})₂B | (Fe_{0.17}Co_{0.41}Ni_{0.17}Mn_{0.24})₂B | (Fe_{0.13}Co_{0.47}Ni_{0.20}Mn_{0.20})₂B |
| C | (Fe_{0.22}Co_{0.33}Ni_{0.22}Mn_{0.22})₂B | (Fe_{0.21}Co_{0.38}Ni_{0.21}Mn_{0.21})₂B | (Fe_{0.14}Co_{0.43}Ni_{0.25}Mn_{0.18})₂B |
| D | (Fe_{0.25}Co_{0.29}Ni_{0.25}Mn_{0.21})₂B | (Fe_{0.21}Co_{0.36}Ni_{0.25}Mn_{0.18})₂B | (Fe_{0.17}Co_{0.38}Ni_{0.31}Mn_{0.14})₂B |
| E | (Fe_{0.24}Co_{0.24}Ni_{0.31}Mn_{0.21})₂B | (Fe_{0.24}Co_{0.28}Ni_{0.31}Mn_{0.17})₂B | (Fe_{0.23}Co_{0.26}Ni_{0.35}Mn_{0.16})₂B |
| F | (Fe_{0.32}Co_{0.24}Ni_{0.28}Mn_{0.16})₂B | (Fe_{0.26}Co_{0.22}Ni_{0.37}Mn_{0.15})₂B | (Fe_{0.25}Co_{0.25}Ni_{0.39}Mn_{0.11})₂B |
| G | (Fe_{0.33}Co_{0.15}Ni_{0.33}Mn_{0.19})₂B | (Fe_{0.28}Co_{0.19}Ni_{0.41}Mn_{0.12})₂B | (Fe_{0.20}Co_{0.23}Ni_{0.43}Mn_{0.13})₂B |

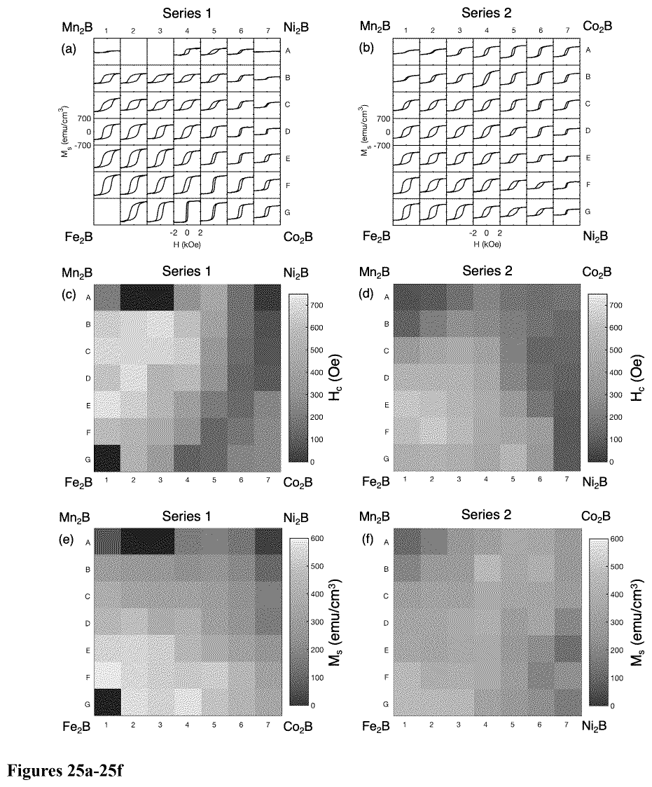

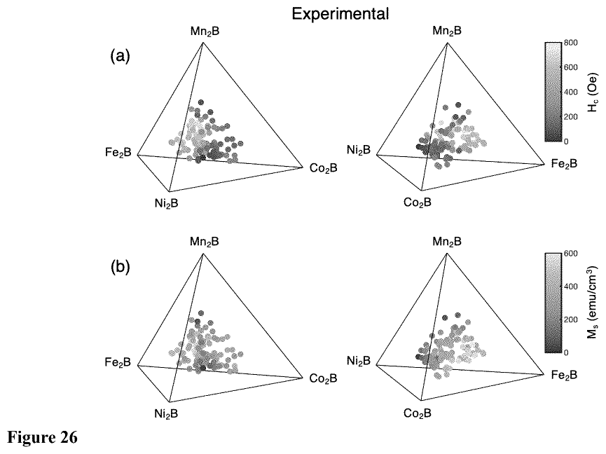

In-pane hysteresis loops for the combinatorial samples were collected at room-temperature using VSM, shown in FIGS. 25a-b. Heat maps of the coercivity H, and saturation magnetization Mₛ for both series are shown in FIGS. 25c-f. Samples 1-A2, 1-A3, and 1-G1 are omitted due to oxidation of the sample during annealing. The sample with the highest H_{c} overall was sample 1-E1 with composition (Fe_{0.35}Co_{0.17}Ni_{0.17}Mn_{0.31})₂B, exhibiting H_{c}=720 Ge and M₃=536 emu/cm³, indicating substantial magnetic anisotropy. The sample with highest H_{c} in Series 2 was sample 2-F2 with composition (Fe_{0.45}Co_{0.16}Ni_{0.16}Mn_{0.19})₂B, H_{c}=640 Ge and Mₛ=393 emu/cm³. Meanwhile, the highest Mₛ was found for sample 1-F1 with composition (Fe_{0.41}Co_{0.18}Ni_{0.14}Mn_{0.27})₂B, exhibiting Mₛ=591 emu/cm³ and H_{c}=580 Oe. The high magnetizations of Co-rich and Fe-rich samples is consistent with the relatively high moments of 1.89μ_{B} and 0.80μ_{B} for Fe and Co in Fe₂B and Co₂B, respectively. Meanwhile, a discernible trend is the reduction in magnetization at higher concentrations of either Ni or Mn. This is consistent with the reported paramagnetic and antiferromagnetic ordering of Ni₂B and Mn₂B, respectively. The sample with the lowest Mₛ and H_{c} was sample 1-A7 with Ni-rich composition (Fe_{0.12}Co_{0.24}Ni_{0.48}Mn_{0.16})₂B, and was the only sample with no ferromagnetic signal at room-temperature. This composition notably has the highest Ni:Fe ratio of all samples. The sample with the second lowest Mₛ was sample 1-A1 with Mn-rich composition of (Fe_{0.17}Co_{0.13}Ni_{0.22}Mn_{0.48})₂B, H_{c}=209 Oe and Mₛ=69 emu/cm³. While both Ni and Mn substantially reduce Mₛ at high concentrations, a moderate concentration of Mn is effective in enhancing H_{c}, being the metal with second highest concentration in the sample with highest measured H_{c} (1-E1). The H_{c} and Mₛ values for all samples are plotted in quaternary diagrams (FIG. 26) based on the EDX-determined TM concentrations listed in Table 2.

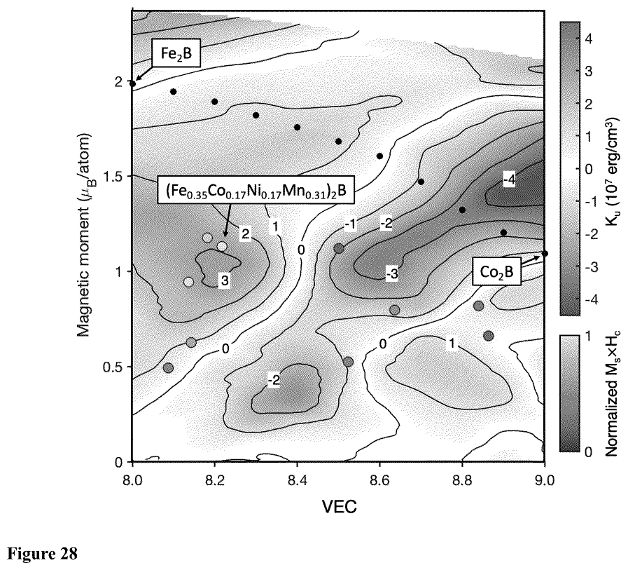

FIG. 28 illustrates the mechanism of the high anisotropy in terms of the optimization of the electronic structure. The figure shows a map of theoretical magnetic anisotropy energy for (Fe₁₋ₓCoₓ)₂B as a function of the average number of valence electrons (VEC) and average local moment on the TM site, replotted from Edstrom et al. [Phys. Rev. B, 92, 062408 (2015)]. The black circles represent the calculated values for (Fe₁₋ₓCoₓ)₂B. The compositional dependence of the anisotropy in (Fe₁₋ₓCoₓ)₂B primarily arises from the shift in Fermi level with respect to coupled minority spin states. This is determined both by the exchange splitting, related to the average local moment, and the effective number of valence electrons which changes with Co concentration. In (Fe₁₋ₓCoₓ)₂B, the optimal band-filling for high positive Kᵤ is achieved at a VEC between 8.3 and 8.4, corresponding to a Co concentration of x=0.3. A peak in the magnetic anisotropy of over 3×10⁷ erg/cm³, more than 3 times greater than the maximum anisotropy of the ternary (Fe₁₋ₓCoₓ)₂B system, is predicted at VEC≈8.2 for a moment of ~1μ_{B}. While the composition (Fe_{0.8}Co_{0.2})₂B satisfies the condition of VEC=8.2, its TM moment (~1.8 M_{B}) is much larger than the required ~1 μB.

Because Mn and Ni have VECs of 7 and 10, respectively, a combination of Ni and Mn can exhibit any VEC between 7 and 10, depending on the Mn:Ni ratio. In the boride phase, Mn carries a non-zero magnetic moment which is expected to be lower than that of Fe. Meanwhile, Ni is expected to have zero magnetic moment. Therefore, a suitable combination Ni and Mn should exhibit a lower magnetic moment than a mixture of Fe and Co, allowing a reduction in the average moment by inclusion of both Ni and Mn, while the Mn:Ni ratio can be controlled to achieve the desired VEC. Because of these facts, both the magnetic moment and VEC can be simultaneously tuned with the proper selection of Mn:Ni ratio and Fe:Co ratios.

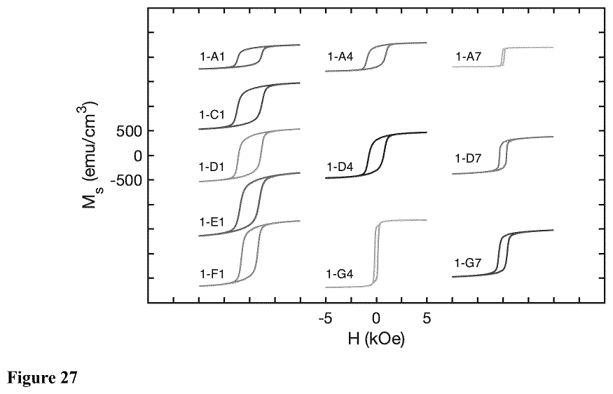

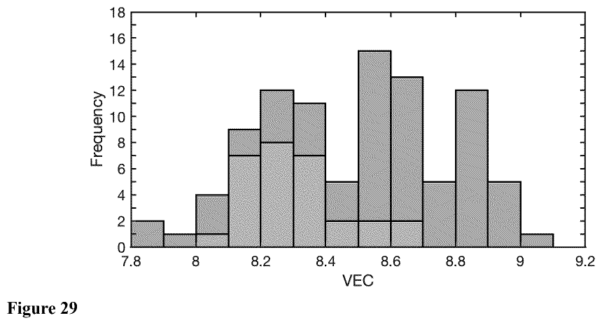

To compare the (FeₓCo_{y}Ni_{z}Mn_{1-x-y-z})₂B samples in the present work with the map of FIG. 28, the average TM moment and VEC may be estimated for select samples measured at 5 K (FIG. 27). The average TM moment is estimated from the volume Mₛ measured in SQUID at 5 K using the lattice parameters of the equimolar sample (FIG. 23a). A small negative boron moment was subtracted from the total moment per unit cell, estimated as the composition weighted average of reported boron moments in Fe₂B, Co₂B, Ni₂B and Mn₂B. The VEC was calculated based on the TM compositions listed in Table 2. The sample composition (Fe_{0.35}Co_{0.17}Ni_{0.17}Mn_{0.31})₂B which showed the highest room-temperature coercivity exhibits a VEC of 8.22 estimated from EDX, and an average local moment of 1.13μ_{B} estimated from the magnetization measured at 5 K via SQUID magnetometer. These are close to the values for optimized anisotropy, as shown in FIG. 28. The mixing of Ni and Mn onto the TM sublattice with Fe and Co allows a reduction in the average local moment due to the reduced Ni and Mn moments, while the VEC can be maintained in the optimal region for certain Ni:Mn ratios due to the valence electron numbers of 10 for Ni and 7 for Mn. FIG. 29 illustrates the distribution of VEC for all combinatorial samples. The VEC are distributed throughout the range of 7.8 to 9.1. The distribution of VEC for samples with room-temperature H_{c}>500 Oe is shown by the gold-colored bins. Notably, these high H_{c} samples are most concentrated within the range of 8.1<VEC<8.4, which comprises the region of highest positive Kᵤ in FIG. 28. Thus, it is suggested that the high anisotropy in C16 high entropy borides is due to an optimized electronic structure achieved through simultaneous tuning of the VEC and local moment.

Thus, as described herein in the disclosed methods, experiments and results, high magnetic anisotropy in novel rare-earth and precious metal-free C16-ordered high entropy boride films is demonstrated. Equimolar (FeCoNiMn)₂B films exhibit clear C16 chemical ordering after RTA as shown by XRD. While the equimolar films exhibit ferromagnetic properties, their anisotropy is modest. To optimize the anisotropy in the wider composition space, a combinatorial fabrication process was employed and used to map the magnetic properties as a function of the transition metal composition. This led to the discovery of novel boride compositions exhibiting high coercivity and expected anisotropy exceeding the maximum anisotropy reported for (Fe₁₋ₓCoₓ)₂B. This is consistent with previous theoretical investigations predicting increased anisotropy at specific values of the local moment and effective valence electron number.

What is claimed is:

1. A composition comprising:
boron; and
a plurality of transition metals including iron (Fe), cobalt (Co), nickel (Ni), and manganese (Mn),
wherein:
an atomic ratio of boron to total transition metals ranges from 20:80 to 45:55;
Fe is present in an amount from 25% to 40% of the total transition metal content;
Co is present in an amount from 5% to 20% of the total transition metal content;
Ni is present in an amount from 5% to 20% of the total transition metal content; and
Mn is present in an amount from 20% to 35% of the total transition metal content.

2. The composition of claim 1, wherein the boron and transition metals form a C16-type crystalline phase upon annealing.

3. The composition of claim 1, wherein the borides are provided via co-sputtering of Fe₂B, Co₂B, Ni₂B, and Mn₂B targets.

4. The composition of claim 1, wherein the borides are provided via sputtering of a composite target comprising B, Fe, Co, Ni, and Mn, wherein the atomic percent of boron is approximately 33% and the remaining 67% of the composition comprises Fe, Co, Ni, and Mn.

5. The composition of claim 1, wherein the borides are provided via sputtering of multiple elemental or composite targets comprising B, Fe, Co, Ni, and Mn and their alloys or compounds, wherein the atomic percent of boron in the borides is approximately 33% and the remaining 67% of the composition comprises Fe, Co, Ni, and Mn.

6. The composition of claim 1, wherein an atomic percent of boron is approximately 33% and the remaining 67% of the composition comprises Fe, Co, Ni, and Mn.

7. The composition of claim 1, wherein the composition-weighted average number of valence electrons of the transition metal atoms is between 8.0 and 8.4.

8. The composition of claim 1, wherein the composition-weighted average magnetic moment of the transition metal component is between 0.8 and 1.2μ_{B}.

9. The composition of claim 1, wherein the composition exhibits a coercivity greater than 600 Oe after rapid thermal annealing.

10. The composition of claim 1, wherein the composition is ferromagnetic and rare-earth-free.

11. The composition of claim 1, wherein the composition exhibits enhanced magnetocrystalline anisotropy as a result of the combined presence of Fe, Co, Ni, and Mn.

12. A method of forming a composition, comprising:
co-sputtering Fe₂B, Co₂B, Ni₂B, and Mn₂B onto a substrate; and
annealing the deposited film at a temperature between 500° C. and 900° C. for a duration of 3 to 240 seconds.

13. The method of claim 12, wherein the resulting film comprises boron and transition metals including Fe, Co, Ni, and Mn, with a boron-to-transition metal atomic ratio between 20:80 and 45:55.

14. The method of claim 12, wherein the co-sputtering is performed in an ultrahigh vacuum deposition chamber having a base pressure of less than 1×10⁻⁷ Torr.

15. The method of claim 12, wherein the substrate comprises Si.

16. The method of claim 12, wherein the substrate comprises a thermally oxidized Si having an amorphous SiO₂ layer.

17. The method of claim 12, wherein the substrate comprises amorphous SiO₂.

18. The method of claim 12, wherein the sputtering is performed at room temperature in an argon environment at a working pressure between 2 mTorr and 5 mTorr.

19. The method of claim 12, wherein the relative ratios of Fe, Co, Ni, and Mn are controlled by adjusting the individual sputtering power and/or orientation of each boride target with respect to the substrate.

20. The method of claim 12, wherein the film is capped with a 1-3 nm tantalum layer following deposition.

21. The method of claim 12, wherein the annealing is performed by rapid thermal annealing (RTA) in a vacuum environment.

22. The method of claim 12, wherein the RTA is performed by transferring the substrate into a heating zone under vacuum and irradiating with a heating lamp for a predetermined annealing time.

23. The method of claim 12, wherein the deposited film crystallizes into a C16 boride phase upon annealing.

24. The method of claim 12, wherein the resulting film exhibits a coercivity greater than 500 Oe and a saturation magnetization between 200 and 800 emu/cm³.

25. A method of forming a high-entropy boride film, comprising:
sputtering a film onto a substrate using a composite sputtering target consisting essentially of boron and a plurality of transition metals including iron (Fe), cobalt (Co), nickel (Ni), and manganese (Mn),
wherein:
an atomic ratio of boron to total transition metals ranges from 20:80 to 45:55;
Fe is present in an amount from 25% to 40% of the total transition metal content;
Co is present in an amount from 5% to 20% of the total transition metal content;
Ni is present in an amount from 5% to 20% of the total transition metal content; and
Mn is present in an amount from 20% to 35% of the total transition metal content and
annealing the sputtered film at a temperature between 500° C. and 900° C. for a duration of 3 to 240 seconds, wherein the resulting film comprises boron and a transition metal alloy including Fe, Co, Ni, and Mn, with a boron-to-transition metal atomic ratio between 20:80 and 45:55.

26. The method of claim 25, wherein the sputtering is performed in an ultrahigh vacuum deposition chamber having a base pressure of less than 1×10⁻⁷ Torr.

27. The method of claim 25, wherein the substrate comprises Si.

28. The method of claim 25, wherein the substrate comprises thermally oxidized Si having an amorphous SiO₂ layer.

29. The method of claim 25, wherein the substrate comprises amorphous SiO₂.

30. The method of claim 25, wherein the sputtering is performed at room temperature in an argon environment at a working pressure between 2 mTorr and 5 mTorr.

31. The method of claim 25, wherein the film is capped with a tantalum layer following deposition.

32. The method of claim 25, wherein the annealing is performed by rapid thermal annealing (RTA) in a vacuum environment.

33. The method of claim 25, wherein the RTA is performed by transferring the substrate into a heating zone under vacuum and irradiating with a heating lamp for a predetermined annealing time.

34. The method of claim 25, wherein the deposited film crystallizes into a C16 boride phase upon annealing.

35. The method of claim 25, wherein the resulting film exhibits a coercivity greater than 500 Oe and a saturation magnetization between 200 and 800 emu/cm³.
